(19) United States
(12) Patent Application Publication
(10) Pub. No.: US 2025/0040129 A1
(43) Pub. Date: Jan. 30, 2025

(54) SEMICONDUCTOR DEVICE INCLUDING ACTIVE REGION AND BIT LINE

(71) Applicant: Samsung Electronics Co., Ltd., Suwon-si (KR)

(72) Inventors: Seungbo KO, Suwon-si (KR); Inwoo KIM, Suwon-si (KR); Jongmin KIM, Suwon-si (KR); Kiseok LEE, Suwon-si (KR); Minyoung LEE, Suwon-si (KR); Seongtak CHO, Suwon-si (KR); Inho CHA, Suwon-si (KR)

(73) Assignee: Samsung Electronics Co., Ltd., Suwon-si (KR)

(21) Appl. No.: 18/655,731

(22) Filed: May 6, 2024

(30) Foreign Application Priority Data
Jul. 24, 2023 (KR) 10-2023-0096106

(51) Int. Cl. H10B 12/00

(52) U.S. Cl. CPC H10B 12/485; H10B 12/315; H10B 12/482

(57) ABSTRACT

A semiconductor device may include a device isolation layer on a side of the active region, a gate trench intersecting the active region, a gate structure in the gate trench, a bit line electrically connected to a first region of the active region, and a pad pattern electrically connected to a second region of the active region. An upper surface of the second region may be higher than an upper surface of the first region and lower than an upper surface of the bit line. A width of the bit line may be greater in an upper region than a lower region thereof. The pad pattern may contact upper and side surfaces of the second region. An upper surface of the pad pattern may be higher than an upper surface of the bit line. The gate trench may be between the first and second regions of the active region.

### CROSS-REFERENCE TO RELATED APPLICATION(S)

This application claims benefit of priority to Korean Patent Application No. 10-2023-0096106, filed on Jul. 24, 2023 in the Korean Intellectual Property Office, the disclosure of which is incorporated herein by reference in its entirety.

### BACKGROUND

Example embodiments of the present disclosure relate to a semiconductor device including an active region and bit lines.

Research has been conducted to reduce sizes of elements included in a semiconductor device and to improve performance. For example, in a DRAM, research has been conducted to reliably and stably form components having reduced sizes, but as the sizes of components are reduced, distribution properties of a semiconductor device may be deteriorated.

### SUMMARY

An example embodiment of the present disclosure provides a semiconductor device which may improve integration density.

An example embodiment of the present disclosure provides a method of manufacturing a semiconductor device.

According to an example embodiment of the present disclosure, a semiconductor device may include an active region; a device isolation layer on a side surface of the active region; a gate trench intersecting the active region and extending into the device isolation layer, the active region including a first region and a second region spaced apart from each other by the gate trench; a gate structure in the gate trench; a bit line electrically connected to the first region of the active region; and a pad pattern electrically connected to the second region of the active region. An upper surface of the second region of the active region may be higher than an upper surface of the first region of the active region and lower than an upper surface of the bit line. A width of an upper region of the bit line may be greater than a width of a lower region of the bit line. The pad pattern may be in contact with the upper surface of the second region of the active region and a side surface of the second region of the active region. An upper surface of the pad pattern may be higher than the upper surface of the bit line.

According to an example embodiment of the present disclosure, a semiconductor device may include active regions; a device isolation layer on side surfaces of the active regions; gate trenches intersecting the active regions and extending into the device isolation layer; gate structures in the gate trenches, each of the active regions including a first region and a second region spaced apart from each other by one of the gate structures; bit line structures connected to the first regions of the active regions; and pad patterns connected to the second regions of the active regions. Each of the gate structures may have a line shape extending in a first direction. Each of the bit line structures may have a line shape extending in a second direction and the second direction may be perpendicular to the first direction. The active regions may be arranged in the first direction and a third direction. The third direction may be diagonal with respect to the first direction. The first regions of the active regions and the second regions of the active regions may be alternately arranged in the first direction between gate structures adjacent each other among the gate structures. Each of the bit line structures may include a bit line and a bit line capping layer on the bit line such that the bit line structures may include bit lines and bit line capping layers. The bit lines may be connected to the first regions of the active regions, respectively, and each of the bit line structures may include a side surface having a negative slope.

According to an example embodiment of the present disclosure, a semiconductor device may include active regions; a device isolation layer on side surfaces of the active regions; the gate trenches intersecting the active regions and extending into the device isolation layer; gate structures in the gate trenches, each of the active regions including a first region and a second region spaced apart from each other by one of the gate structures, and each of the gate structures having a line shape extending in a first direction; bit line structures connected to the first regions of the active regions, each of the bit line structures having a line shape extending in a second direction, the second direction being perpendicular to the first direction; pad patterns between the bit line structures and connected to the second regions of the active regions; insulating separation patterns including first separation portions, the first separation patterns being between the pad patterns spaced apart from each other in the second direction, and the first separation patterns being between the bit line structures spaced apart from each other in the first direction; and spacer structures on side surfaces of the bit line structures, the spacer structures being between the bit line structures and the pad patterns, and the spacer structures being between the bit line structures and the insulating separation patterns. Each of the gate structures may include a gate dielectric layer on an internal wall of the gate trench, a gate electrode partially filling the gate trench on the gate dielectric layer, and a gate capping insulating layer on the gate electrode. Each of the active regions may have a major axis extending in a direction diagonal to the first direction. The first regions of the active regions and the second regions of the active regions may be alternately arranged in the first direction between gate structures adjacent to each other among the gate structures. Each of the bit line structures may include a bit line connected to the first regions of the active regions and a bit line capping layer on the bit line. The insulating separation patterns may further include second separation portions and the second separation portions may extend in the first direction from the first separation portions to upper surfaces of the bit line structures or the second separation portions may extend in the first direction from the first separation portions to a region below lower surfaces of the bit line structures.

### BRIEF DESCRIPTION OF DRAWINGS

The above and other aspects, features, and advantages of the present disclosure will be more clearly understood from the following detailed description, taken in combination with the accompanying drawings, in which:

FIGS. 1A, 1B, 1C, 1D, 2A, 2B, 3A, and 3B are diagrams illustrating a semiconductor device according to an example embodiment of the present disclosure;

FIGS. 4 and 5 are cross-sectional diagrams illustrating a semiconductor device according to an example embodiment of the present disclosure;

FIG. 6A is an enlarged cross-sectional diagram illustrating a modified example of a semiconductor device according to an example embodiment of the present disclosure;

FIG. 6B is an enlarged cross-sectional diagram illustrating a modified example of a semiconductor device according to an example embodiment of the present disclosure;

FIG. 7A is an enlarged cross-sectional diagram illustrating a modified example of a semiconductor device according to an example embodiment of the present disclosure;

FIG. 7B is an enlarged cross-sectional diagram illustrating a modified example of a semiconductor device according to an example embodiment of the present disclosure;

FIG. 7C is an enlarged cross-sectional diagram illustrating a modified example of a semiconductor device according to an example embodiment of the present disclosure;

FIG. 8A is a cross-sectional diagram illustrating a modified example of a semiconductor device according to an example embodiment of the present disclosure;

FIG. 8B is a cross-sectional diagram illustrating a modified example of a semiconductor device according to an example embodiment of the present disclosure;

FIG. 8C is a cross-sectional diagram illustrating a modified example of a semiconductor device according to an example embodiment of the present disclosure;

FIG. 8D is a cross-sectional diagram illustrating a modified example of a semiconductor device according to an example embodiment of the present disclosure;

FIG. 8E is a cross-sectional diagram illustrating a modified example of a semiconductor device according to an example embodiment of the present disclosure;

FIG. 8F is a cross-sectional diagram illustrating a modified example of a semiconductor device according to an example embodiment of the present disclosure;

FIG. 9A is an enlarged cross-sectional diagram illustrating a modified example of a portion of a semiconductor device according to an example embodiment of the present disclosure;

FIG. 9B is an enlarged cross-sectional diagram illustrating a modified example of a portion of a semiconductor device according to an example embodiment of the present disclosure;

FIG. 9C is an enlarged cross-sectional diagram illustrating a modified example of a portion of a semiconductor device according to an example embodiment of the present disclosure;

FIG. 10A is an enlarged cross-sectional diagram illustrating a modified example of a portion of a semiconductor device according to an example embodiment of the present disclosure;

FIG. 10B is an enlarged cross-sectional diagram illustrating a modified example of a portion of a semiconductor device according to an example embodiment of the present disclosure;

FIG. 11A is a diagram illustrating a modified example of a semiconductor device according to an example embodiment of the present disclosure, viewed from above;

FIG. 11B is a diagram illustrating a modified example of a semiconductor device according to an example embodiment of the present disclosure, viewed from above;

FIG. 11C is a diagram illustrating a modified example of a semiconductor device according to an example embodiment of the present disclosure, viewed from above;

FIG. 11D is a diagram illustrating a modified example of a semiconductor device according to an example embodiment of the present disclosure, viewed from above;

FIG. 11E is a diagram illustrating a modified example of a semiconductor device according to an example embodiment of the present disclosure, viewed from above;

FIG. 11F is a diagram illustrating a modified example of a semiconductor device according to an example embodiment of the present disclosure, viewed from above;

FIG. 11G is a diagram illustrating a modified example of a semiconductor device according to an example embodiment of the present disclosure, viewed from above;

FIGS. 12A and 12B are diagrams illustrating a modified example of a semiconductor device according to an example embodiment of the present disclosure, viewed from above;

FIG. 13 is a diagram illustrating a modified example of a semiconductor device according to an example embodiment of the present disclosure, viewed from above;

FIGS. 14 and 15 are cross-sectional diagrams illustrating a modified example of a semiconductor device according to an example embodiment of the present disclosure;

FIGS. 16 and 17 are cross-sectional diagrams illustrating a modified example of a semiconductor device according to an example embodiment of the present disclosure;

FIGS. 18 and 19 are cross-sectional diagrams illustrating a modified example of a semiconductor device according to an example embodiment of the present disclosure;

FIGS. 20A to 25B are cross-sectional diagrams illustrating a method of manufacturing a semiconductor device according to an example embodiment of the present disclosure; and

FIGS. 26A to 29B are cross-sectional diagrams illustrating a method of manufacturing a semiconductor device according to an example embodiment of the present disclosure.

### DETAILED DESCRIPTION

Hereinafter, embodiments of the present disclosure will be described as follows with reference to the accompanying drawings.

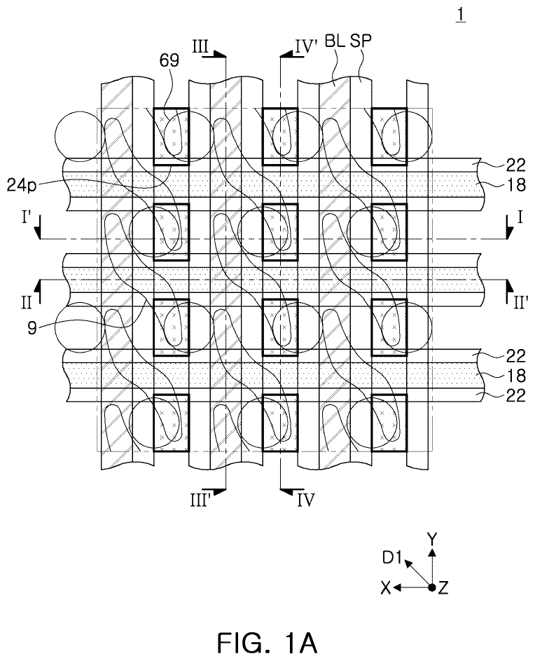

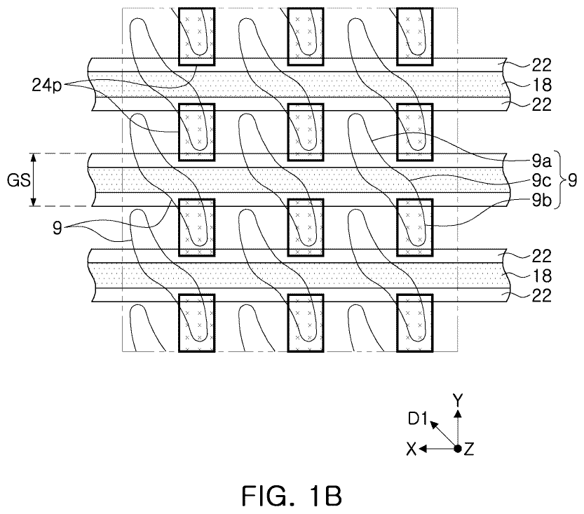

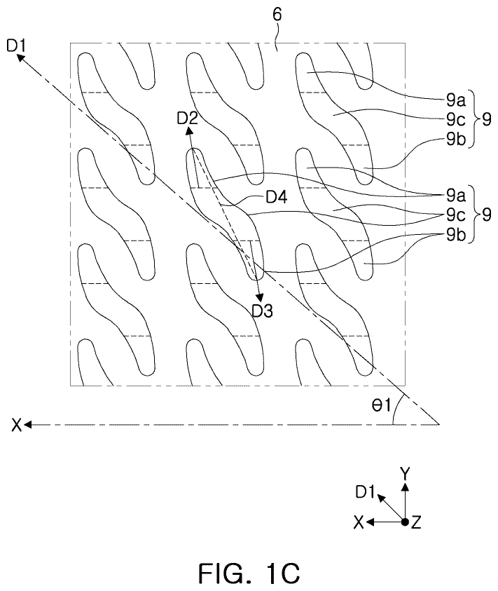

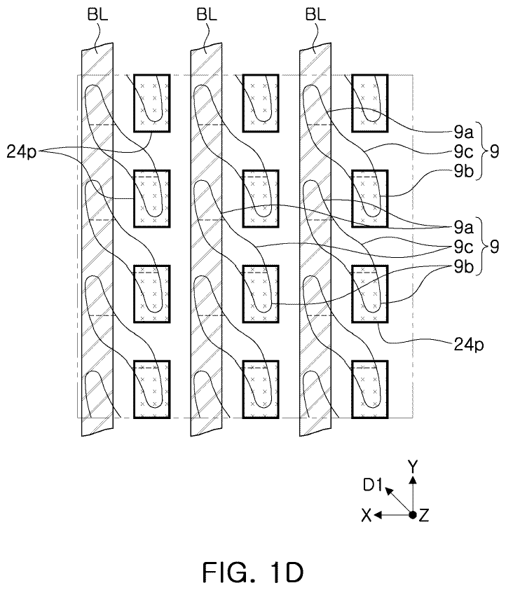

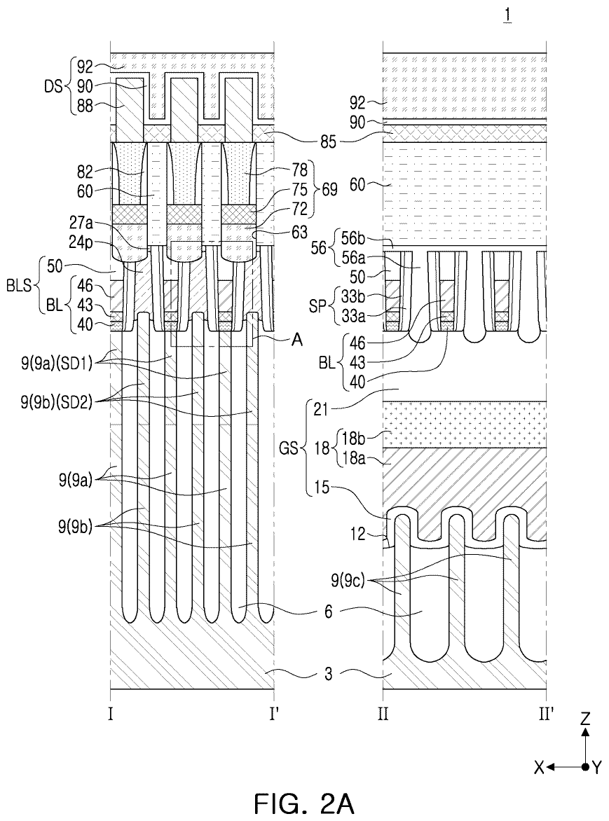

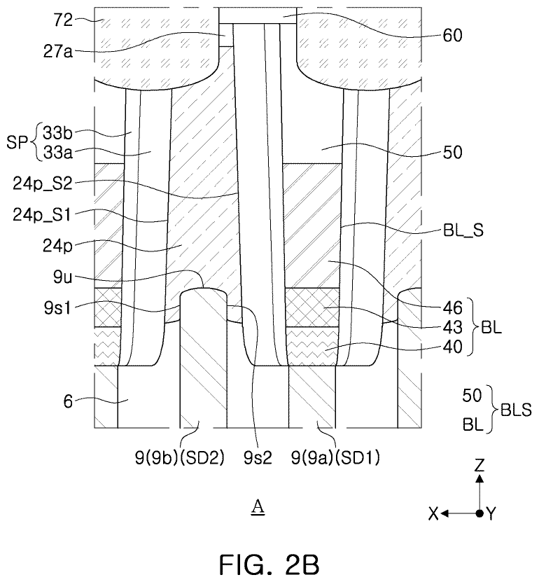

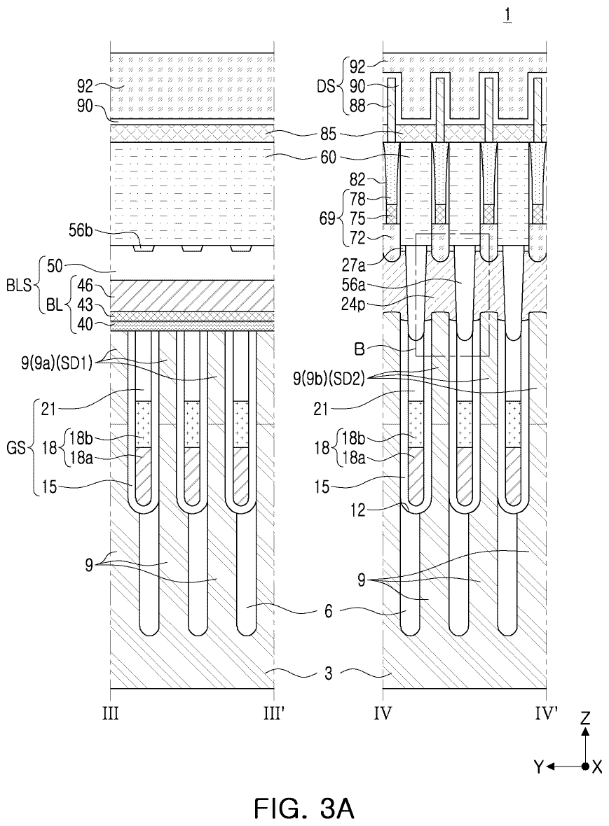

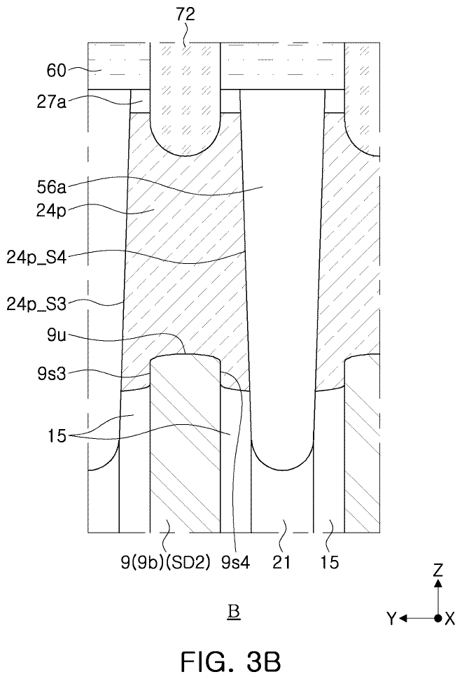

A semiconductor device according to an example embodiment will be described with reference to FIGS. 1A, 1B, 1C, 1D, 2A, 2B, 3A, and 3B. FIG. 1A is a diagram illustrating a semiconductor device according to an example embodiment, viewed from above. FIGS. 1B, 1C, and 1D are diagrams illustrating a portion of components in FIG. 1A. FIG. 2A is a cross-sectional diagram illustrating regions taken along lines I-I′ and II-II′ in FIG. 1A. FIG. 2B is an enlarged diagram illustrating a region “A” in FIG. 2A. FIG. 3A is a cross-sectional diagram illustrating regions taken along lines III-III′ and IV-IV′ in FIG. 1A. FIG. 3B is an enlarged diagram illustrating region “B” in FIG. 3A.

Referring to FIGS. 1A to 3B, a semiconductor device 1 according to an example embodiment may include a substrate 3, active regions 9, a device isolation layer 6, gate trenches 12, gate structures GS, bit line structures BLS, and pad patterns 24p.

The substrate 3 may be provided as a bulk wafer, an epitaxial layer, a silicon on insulator layer (SOI), or a semiconductor on insulator layer (SeOI). The substrate 3 may include a group IV semiconductor, a group III-V compound semiconductor, or a group II-VI compound semiconductor. For example, the substrate 3 may be a substrate including at least one of silicon, silicon carbide, germanium, or silicon-germanium. For example, the substrate 3 may be a silicon material, for example, a single crystal silicon substrate including a single crystal silicon material.

The active regions 9 may be disposed on the substrate 3. The active regions 9 may have a shape protruding from the substrate 3 upwardly of the substrate 3. Accordingly, the active regions 9 may include the same material as that of the substrate 3, for example, single crystal silicon.

The device isolation layer 6 may be configured as a trench device isolation layer which may be formed by a trench device isolation process. The device isolation layer 6 may be formed of an insulating material. For example, the device isolation layer 6 may include at least one of silicon oxide, low dielectric, silicon oxynitride (SiON), and silicon nitride. The low dielectric material may have a dielectric constant smaller than that of silicon oxide.

The gate trenches 12 may intersect the active regions 9 and may extend into the device isolation layer 6. The gate structures GS may be disposed in the gate trenches 12.

Each of the gate structures GS may have a line shape extending in the X-direction.

Each of the gate structures GS may include a gate dielectric layer 15 on the internal wall of the gate trench 12, a gate electrode 18 partially filling the gate trench 12 on the gate dielectric layer 15, and a gate capping layer on the gate electrode 18.

The gate dielectric layer 15 may include at least one of silicon oxide and a high dielectric material. The high dielectric material may have a dielectric constant greater than that of silicon oxide. For example, the gate dielectric layer 15 may include at least one of silicon oxide, hafnium oxide (HfO), hafnium-based oxide (Hf-based oxide), aluminum oxide (AlO), aluminum-based oxide (Al-based oxide), lanthanum oxide (LaO), lanthanum-based oxide (La-based oxide), magnesium oxide (MgO), and magnesium oxide (Mg-based oxide).

The gate electrode 18 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or a combination thereof, but an example embodiment thereof is not limited thereto. The gate electrode 18 may include a single layer or multiple layers formed of the above-described materials. For example, the gate electrode 18 may include a first gate conductive layer 18a and a second gate conductive layer 18b on the first gate conductive layer 18b. The first gate conductive layer 18b may include a conductive material such as Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, or RuOₓ, and the second gate conductive layer 18b may include doped polysilicon.

The gate capping layer 21 may include an insulating material such as silicon nitride or SiOCN.

Each of the active regions 9 may include a first region 9a and a second region 9b isolated from each other by one of the gate structures GS, and a third region 9c disposed below the gate structure GS.

Each of the active regions 9 may vertically overlap one of the gate structures GS and may not vertically overlap the other gate structures GS. For example, one of the active regions 9 may intersect with one of the gate structures GS.

In each of the active regions 9, an upper surface of the second region 9b may be disposed at a level higher than a level of the upper surface of the first region 9a, and an upper surface of the third region 9c may be disposed at a level lower than a level of the upper surfaces of the first and second regions 9a and 9b.

Each of the active regions 9 may include a first source/drain region SD1 disposed in an upper region of the first region 9a and a second source/drain region SD2 disposed in an upper region of the second region 9b.

In example embodiments, the upper surfaces of the first and second regions 9a and 9b may be the upper surfaces of the first and second source/drain regions SD1 and SD2.

In the X-direction, the gate structures GS may cover an upper surface and side surface of the upper region of the third region 9c of the active regions 9.

The upper surfaces of the first and second regions 9a and 9b of the active regions 9 may be disposed at a level higher than a level of the upper surfaces of the gate electrodes 18.

The active regions 9 may be arranged in the X-direction and the D1 direction inclined at a first angle θ1.

A first angle θ1 may be from about 35 degrees to about 50 degrees.

The description of a planar shape of each of the active regions 9 as illustrated in FIG. 1C will be described with respect to the active region 9.

Referring to FIG. 1C, as described above, the active region 9 may include a third region 9c, which vertically overlaps the gate structure GS, and a first region 9a and a second region 9b spaced apart from each other by the gate structure GS.

The active region 9 may have a D4 major axis. The D4 major axis may extend in a diagonal direction with a slope inclined with respect to the X-direction.

The D4 major axis may have a slope inclined with respect to the D1 direction.

The D2 direction and the D3 direction may have a slope inclined with respect to the D4 major axis.

The central region of the third region 9c may extend in the D1 direction, one side of the third region 9c may be bent in the D2 direction, and the other side of the third region 9c may be bent in the D3 direction. Accordingly, in the diagram as illustrated in FIG. 1C, the active region 9 may have a shape extending to the upper left when viewed with respect to the central region of the third region 9c, in which the first region 9a extends in the D1 direction, and the second region 9b may have a shape extending to the lower right. Accordingly, the first region 9a may extend from the third region 9c in the upper left direction, that is, the D2 direction, and the second region 9b may extend from the third region 9c in the lower right direction, that is, the D3 direction. The D2 direction and the D3 direction may be directions having a slope diagonal to the X-direction.

Referring back to FIGS. 1A to 3B, the first region 9a of the active regions 9 may be arranged in a Y-direction perpendicular to the X-direction. The second regions 9b of the active regions 9 may be arranged in the Y-direction. Among the first regions 9a of the active regions 9 and the second regions 9b of the active regions 9, the first and second regions 9a and 9b in different active regions may be disposed between the gate structures GS. For example, among the gate structures GS, the first regions 9a and the second regions 9b in different active regions 9 may be alternately and repeatedly arranged in the X-direction between the gate structures GS adjacent to each other.

The bit line structures BLS may be connected to the first regions 9a of the active regions 9.

Each of the bit line structures BLS may include a bit line BL and a bit line capping layer 50 on the bit line BL.

Each of the bit lines BL may have a line shape extending in a Y-direction perpendicular to the X-direction.

The bit lines BL may be connected to the first region 9a of the active regions 9. The bit lines BL may be electrically connected to the first source/drain regions SD1 of the first regions 9a of the active regions 9. The bit lines BL may be in contact with the first source/drain regions SD1.

Each of the bit lines BL may include at least one conductive material layer. Each of the bit lines BL may include at least one of doped silicon, metal-semiconductor compound, metal-nitride, and metal. Each of the bit lines BL may be formed of doped silicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube or a combination thereof, but an example embodiment thereof is not limited thereto. Each of the bit lines BL may include a single layer or multiple layers of the materials described above. For example, each of the bit lines BL may include a first material layer 40, a second material layer 43 on the first material layer 40, and a third material layer 46 on the second material layer 43. The first to third conductive material layers 40, 43, and 43 may include different materials. The first material layer 40 may be a metal-semiconductor compound layer to form an ohmic contact with the first source/drain region SD1 of the first region 9a, and the second material layer 43 may be a metal nitride or a metal nitride including impurities, and the third material layer 46 may include a metal such as W, Co, Mo, or Ru to lower overall resistance of the bit line BL, but the example embodiment is not limited thereto, and each material layer 40, 43, and 46 may also include other substances.

In the bit lines BL, the doped silicon may be doped polysilicon or doped epitaxial silicon.

The bit line capping layers 50 may include an insulating material such as silicon oxide, SiOC, silicon nitride, or SiOCN.

The lower surface of the bit line structures BLS, that is, the lower surface of the bit lines BL, may be disposed at a level lower than a level of the upper surfaces of the second regions 9b of the active regions 9.

The upper surfaces of the first material layers 40 of the bit lines BL may be disposed at a level lower than a level of the upper surfaces of the second regions 9b.

In each of the bit lines BL, the thickness of the third material layer 46 may be greater than the thickness of each of the first and second material layers 40 and 43.

Each of the bit line structures BLS may have bit line side surfaces BL_S opposing each other in the X-direction.

Each of the bit line side surfaces BL_S may have a negative slope. For example, in a bit line structure BLS, the bit line side surface BL_S may have a negative slope such that a width of the upper region of the bit line structure BLS may be greater than a width of the lower region of the bit line structure BLS. The bit line BL may have a side surface having a negative slope.

A maximum width of the bit line capping layer 50 may be greater than a width of the lower surface of the bit line BL in the X-direction. The upper region of the bit line BL may have a width greater than a width of the lower region of the bit line BL. The upper surface of the bit line BL may have a width greater than a width of the lower surface of the bit line BL.

The pad patterns 24p may be connected to the second regions 9b of the active regions 9. The pad patterns 24p may be electrically connected to and in contact with the second source/drain regions SD2 of the second regions 9b of the active regions 9.

A distance between the pad patterns 24p adjacent to each other in the Y-direction may be smaller than a width of each of the gate structures GS.

The example embodiment will be described with respect to the pad pattern 24p and the second region 9b connected to each other among the pad patterns 24p and the second regions 9b.

The upper region of the pad pattern 24p may have a width smaller than a width of the lower region of the pad pattern 24p. The upper surface of the pad pattern 24p may be disposed at a level higher than a level of the upper surface of the bit line BL. The lower end of the pad pattern 24p may be disposed at a level higher than a level of the lower surface of the bit line BL.

A maximum width of the pad pattern 24p may be greater than a maximum width of the bit line BL in the X-direction.

The pad pattern 24p may have a first pad side surface 24p_S1 and a second pad side surface 24p_S2 opposing each other in the X-direction, and may have a third pad side surface 24p_S3 and fourth pad side surface opposing each other in the Y-direction.

At least one of the first to fourth pad side surfaces 24p_S1, 24p_S2, 24p_S3, and 24p_S4 of the pad pattern 24p may have a positive slope. For example, the first to fourth pad side surfaces 24p_S1, 24p_S2, 24p_S3, and 24p_S4 of the pad pattern 24p may have a positive slope.

A lower end of at least one of the first to fourth pad side surfaces 24p_S1, 24p_S2, 24p_S3, and 24p_S4 of the pad pattern 24p may be disposed at a level lower than a level of the upper surface of the second region 9b.

The pad pattern 24p may cover an upper surface and side surface of the second region 9b. The pad pattern 24p may be in contact with the upper surface 9u and side surfaces 9s1, 9s2, 9s3, and 9s4 of the second region 9b.

The side surfaces of the upper region of the second region 9b may include a first active side surface 9s1 and a second active side surface 9s2 opposing each other in the X-direction, and a third active side surface 9s3 and a fourth active side surface 9s4 facing each other in the Y-direction.

The pad pattern 24p may be in contact with at least one side surface among the first to second active side surfaces 9s1, 9s2, 9s3, and 9s4. For example, the pad pattern 24p may be in contact with the first to second active side surfaces 9s1, 9s2, 9s3, and 9s4.

A lower end of the pad pattern 24p may be disposed at a level lower than a level of the upper surface 9u of the second region 9b. The lower end of the pad pattern 24p may be in contact with the gate dielectric layer 15.

The pad pattern 24p may be formed of a conductive material. For example, the pad pattern 24p may be formed of doped silicon, Al, Cu, Ti, Ta, Ru, W, Mo, Pt, Ni, Co, TiN, TaN, WN, NbN, TiAl, TiAIN, TiSi, TiSiN, TaSi, TaSIN, RuTiN, NiSi, CoSi, IrOx, RuOx, graphene, carbon nanotube, or a combination thereof, but an example embodiment thereof is not limited thereto. The pad pattern 24p may include a single layer or multiple layers formed of the above-described materials. In the pad pattern 24p, the doped silicon may be doped polysilicon or doped epitaxial silicon.

The semiconductor device 1 may further include insulating buffer patterns 27a, spacer structures SP and insulating separation patterns 56.

The insulating buffer patterns 27a may be disposed on the pad patterns 24p. Each of the insulating buffer patterns 27a may be formed of silicon oxide, silicon nitride, SiOC, SiOCN, SiCN, SiBN, or a combination thereof, but an example embodiment thereof is not limited thereto. Each of the insulating buffer patterns 27a may include a single layer or multiple layers formed of the above-described materials.

The spacer structures SP may be disposed on the bit line side surfaces BL_S of the bit line structures BLS.

The spacer structures SP may be in contact with the first and second pad side surfaces 24p_S1 and 24p_S2 of the pad patterns 24p. Lower ends of the spacer structures SP may be disposed at a level lower than a level of lower ends of the pad patterns 24p. The spacer structures SP may be formed of an insulating material. Each of the spacer structures SP may be formed of silicon oxide, silicon nitride, SiOC, SiOCN, SiCN, SiBN, or a combination thereof, but an example embodiment thereof is not limited thereto. Each of the spacer structures SP may include a single layer or multiple layers formed of the above-described materials. For example, each of the spacer structures SP may include a first spacer layer 33a in contact with the bit line structure BLS and a second spacer layer 33b on an external side surface of the first spacer layer 33a. In each of the spacer structures SP, the second spacer layer 33b may be in contact with the pad pattern 24p. A thickness of the first spacer layer 33a may be greater than a thickness of the second spacer layer 33b.

The insulating separation patterns 56 may be disposed between the bit line structures BLS and the spacer structures SP.

The insulating separation patterns 56 may include a first separation portions 56a disposed between the pad patterns 24p and the bit line structures BLS, and a second separation portions 56b extending from upper regions of the first separation portions 56a to upper surfaces of the bit line structures BLS in the X-direction. Each of the insulating separation patterns 56 may be formed of silicon oxide, silicon nitride, SiOC, SiOCN, SiCN, SiBN, or a combination thereof, but an example embodiment thereof is not limited thereto. Each of the insulating separation patterns 56 may include a single layer or multiple layers formed of the materials described above.

Uppermost surfaces of the insulating separation patterns 56, the insulating buffer patterns 27a, and the spacer structures SP and the bit line capping layers 50 may be coplanar with each other.

The semiconductor device 1 may further include an interlayer insulating layer 60 and contact structures 69 disposed in a contact hole 63 penetrating through the interlayer insulating layer 60.

The contact holes 63 may penetrate through the interlayer insulating layer 60 and may extend downwardly. The pad patterns 24p, the bit line capping layers 50, and the spacer structures SP may be exposed by the contact holes 63. The contact structures 69 may include at least one conductive layer. For example, each of the contact structures 69 may include a lower conductive layer 72 connected to the pad pattern 24p, an intermediate conductive layer 75 on the lower conductive layer 72, and an upper conductive layer 78 on the intermediate conductive layer 75. The side surfaces of the lower and intermediate conductive layers 72 and 75 may be vertically aligned. A width of the upper conductive layer 78 may be smaller than a width of the intermediate conductive layer 75.

The semiconductor device 1 may further include an insulating spacer 82 between the side surface of the upper conductive layer 78 and the interlayer insulating layer 60 and an etch stop layer 85 on the interlayer insulating layer 60 and the contact structures 69.

The semiconductor device 1 may further include a data storage structure DS. The data storage structure DS may include first electrodes 88 penetrating through the etch stop layer 85 and electrically connected to the contact structures 69, a second electrode 92 on the first electrodes 88, and a dielectric layer 90 between the first electrodes 88 and the second electrode 92.

In an example, the data storage structure DS may be capacitors for storing data in a DRAM. For example, when the data storage structure DS is a capacitor for storing data in DRAM, the dielectric layer 90 may be configured as a capacitor dielectric layer which may include high dielectric, silicon oxide, silicon nitride, silicon oxynitride, or a combination thereof.

In another example, the data storage structure DS may be a structure for storing data of a memory other than DRAM. For example, in the data storage structure DS, the dielectric layer 90 may include a ferroelectric layer which may store data using a polarization state.

The planar shapes and cross-sectional structures of the active regions 9, the gate structures GS, the bit line structures BLS, the spacer structure SP, and the insulating separation patterns 56 described above may improve integration density of the semiconductor device 1.

According to the example embodiments described above, integration density of the semiconductor device 1 may be improved, reliability of the semiconductor device 1 may be increased, and performance of the semiconductor device 1 may be improved. For example, the arrangement shape of the active regions 9 and the planar shape of each of the active regions 9 as described above may improve integration density of the semiconductor device 1, may increase reliability of the semiconductor device 1, and may improve performance of the semiconductor device 1. For example, the arrangement shape of the active regions 9 and the planar shape of each of the active regions 9 described above may increase the contact area between the first regions 9a of the active regions 9 and the bit lines BL, and may increase the contact area between the second regions 9b of the active regions 9 and the pad patterns 24p, such that contact resistance properties may be improved. Performance of the semiconductor device 1 may be improved.

In the above-described example embodiment, in the pad pattern 24p and the active region 9 in contact with each other among the pad patterns 24p and the active regions 9, the pad pattern 24p may be in contact with the upper surface of the second region 9b of the active region 9, and may also be in contact with the side surface of the second region 9b of the active region 9. Accordingly, since the contact area between the second regions 9b of the active regions 9 and the pad patterns 24p may be increased, contact resistance properties may be improved. Performance of the semiconductor device 1 may be improved.

In the example embodiment described above, the pad patterns 24p may include side surfaces having a positive slope, and the bit line structures BLS may include side surfaces having a negative slope. Accordingly, the pad patterns 24p may be preferentially formed, and a structure for forming the bit line structures BLS may be provided as a cross-sectional structure of the pad patterns 24p and the bit line structures BLS, thereby limiting and/or preventing collapse or a warpage defect of the bit line structures BLS.

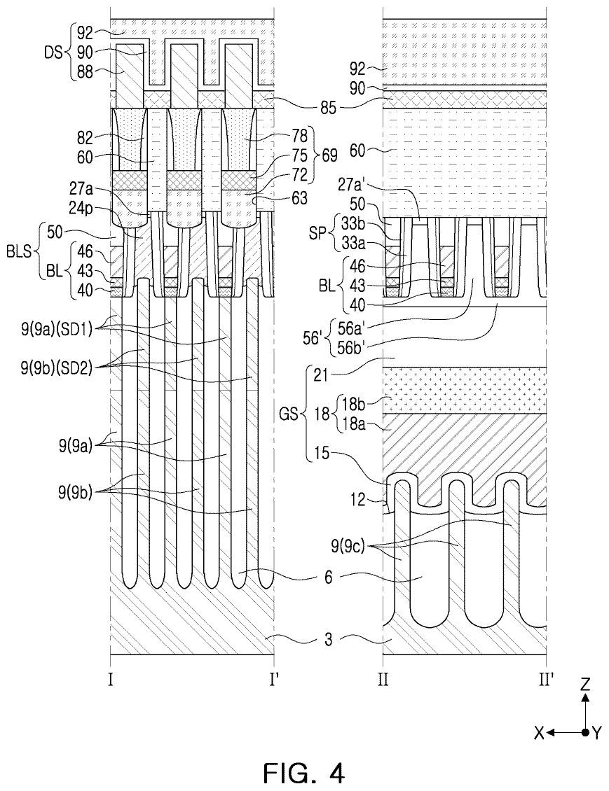

Hereinafter, various modified examples of components in the example embodiment described above will be described with reference to FIGS. 4 to 19. Various modified examples of components in the above-described example embodiment described below will be described with respect to modified or replaced components. Here, the components described above may be not be provide.

Also, the components which may be modified or replaced may improve at least one of connectivity, reliability, and performance of the semiconductor device.

Also, the components which may be modified or replaced may be described with reference to the drawings below, but the components which may be modified or replaced may be combined with each other or with the components described above and may form a semiconductor device in an example embodiment.

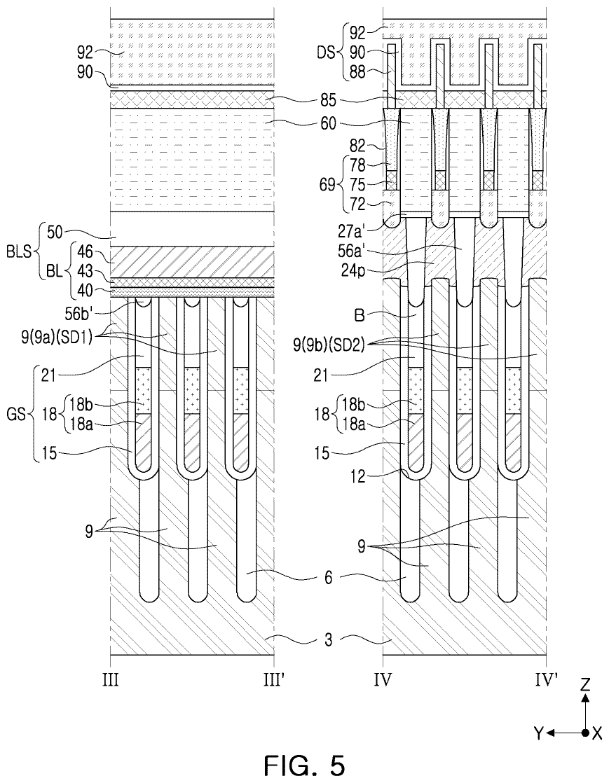

First, a modified example of a semiconductor device according to an example embodiment will be described with reference to FIGS. 4 and 5. FIG. 4 is a cross-sectional diagram illustrating regions taken along lines I-I′ and II-II′ in FIG. 1, and FIG. 5 is a cross-sectional diagram illustrating regions taken along lines III-III′ and IV-IV′ in FIG. 1.

In the modified example, referring to FIGS. 4 and 5, in the insulating separation patterns 56 (see FIGS. 2A to 3B) described above, the second separation portions 56 (see FIGS. 2A to 3B) may not be provided, and the upper surface of the first separation portions (56a of FIGS. 2A to 3B) may be modified to provide a lowered insulating separation pattern 56′. The insulating separation patterns 56′ may be spaced apart from the interlayer insulating layer 60.

The insulating separation patterns 56′ may include first separation portions 56a′ extending in the Z-direction between the pad patterns 24p and in the Z-direction between the bit line structures BLS The insulating separation patterns 56′ may include second separation portions 56b′ extending from the first separation portions 56a′, disposed between the pad patterns 24p and the bit line structures BLS, into the gate capping layers 21 and below the bit lines BL. Accordingly, the insulating separation patterns 56′ may be disposed between the pad patterns 24p and the bit line structures BLS, and between the lower surface of the bit line structures BLS and the gate capping layer 21.

The insulating buffer patterns (27a in FIGS. 2A to 3B) described above may be modified to insulating buffer patterns 27a′ extending to cover the upper surfaces of the insulating separation patterns 56′ on the upper surfaces of the pad patterns 24p. Accordingly, the insulating separation patterns 56′ may be spaced apart from the interlayer insulating layer 60 by the insulating buffer patterns 27a.

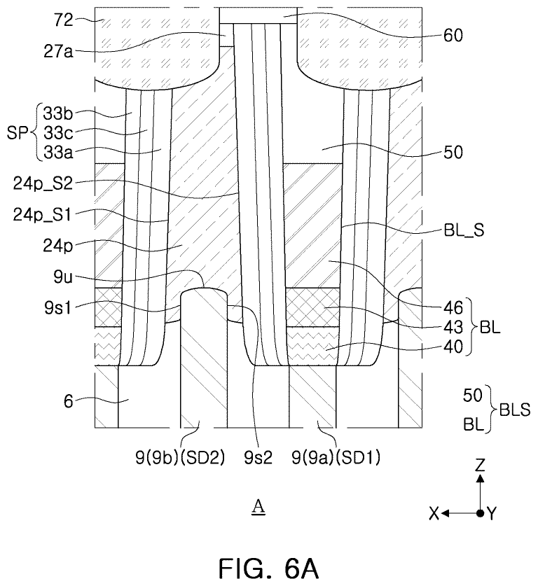

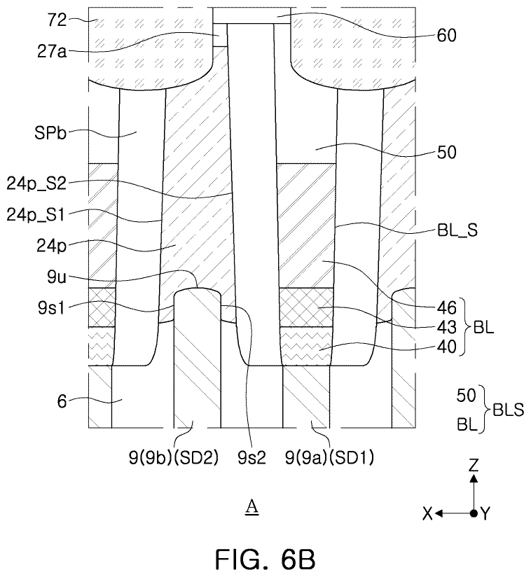

In the description below, various modified examples of the spacer structure (SP in FIGS. 2A and 2B) described above will be described with reference to FIGS. 6A and 6B, respectively. FIGS. 6A and 6B are enlarged diagrams corresponding to the enlarged diagram in FIG. 2B, and illustrating various modified examples of the spacer structure (SP in FIGS. 2A and 2B) described above.

In the modified example, referring to FIG. 6A, the spacer structure (SP in FIGS. 2A and 2B) described above may be modified to a spacer structures Spa including a first spacer layer 33a in contact with the bit line structure BLS, a second spacer layer 33b on an external side surface of the first spacer layer 33a, and a third spacer layer 33c between the first spacer layer 33a and the second spacer layer 33b.

In an example, each of the first, second, and third spacer layers 33a, 33b, and 33c may be formed of silicon oxide, silicon nitride, SiOC, SiOCN, SiCN, SiBN, or a combination thereof.

In another example, each of the first and second spacer layers 33a and 33b may be formed of silicon oxide, silicon nitride, SiOC, SiOCN, SiCN, SiBN, or a combination thereof, and the third spacer layer 33c may be an air spacer.

In the modified example, referring to FIG. 6B, the spacer structure (SP in FIGS. 2A and 2B) including the first and second spacer layers (33a, 33b in FIGS. 2A and 2B) described above may be modified to a spacer structure SPb as in FIG. 6B.

In an example, the spacer structure SPb may be formed as a single material layer.

In another example, the spacer structure SPb may be an air spacer.

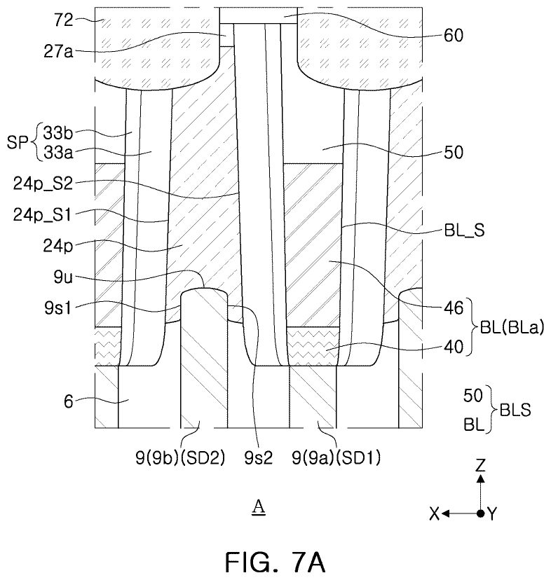

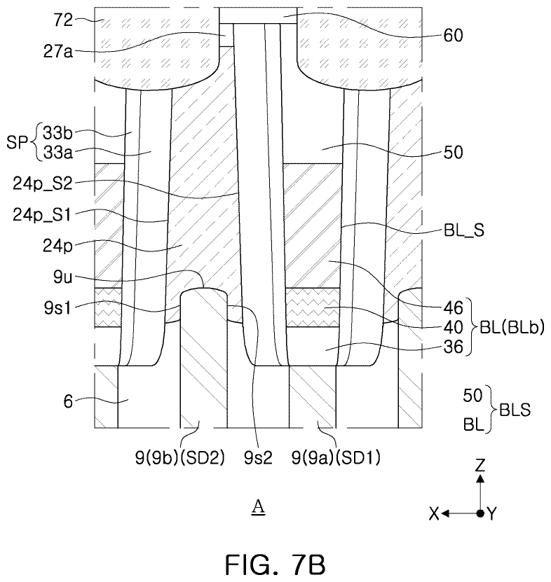

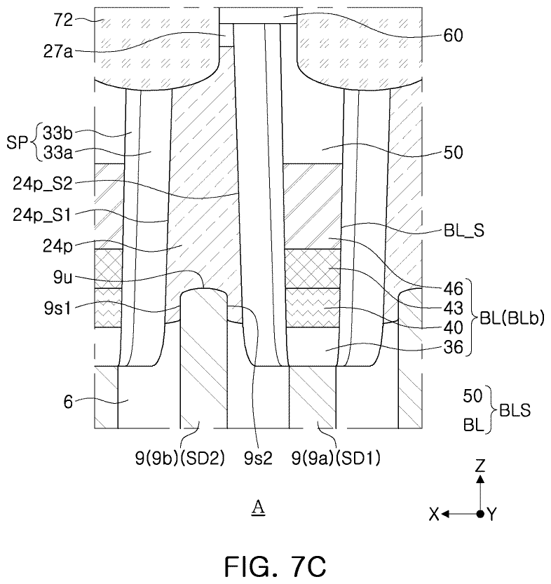

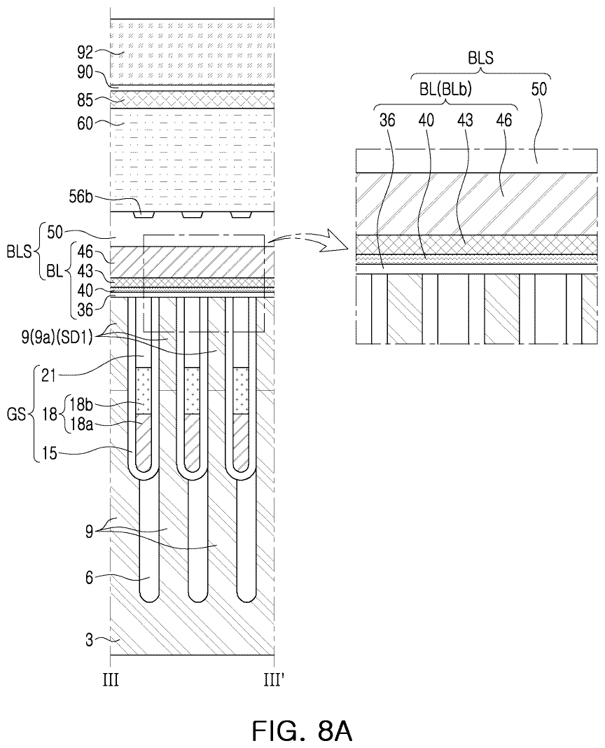

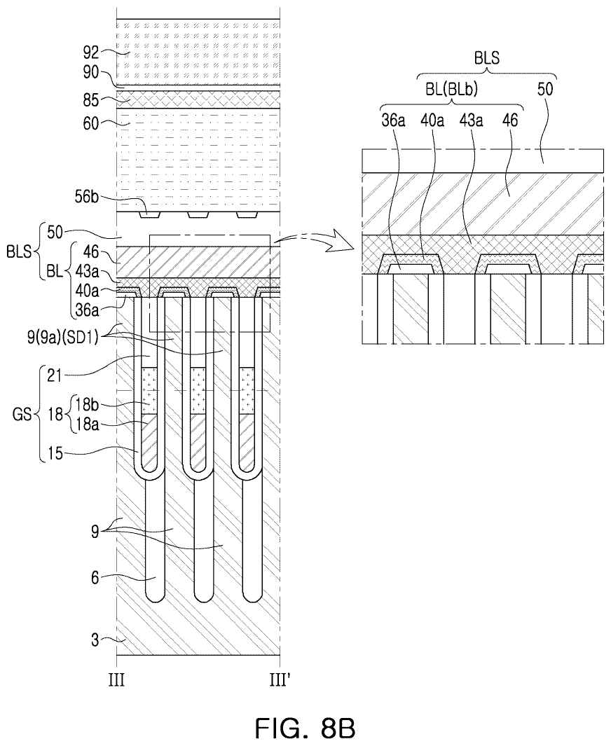

In the description below, various modified examples of the bit line (BL in FIGS. 2A to 3B) described above will be described with reference to FIGS. 7A, 7B and 7C. FIGS. 7A, 7B and 7C are enlarged diagrams corresponding to the enlarged diagram in FIG. 2B, and illustrating various modified examples of the bit line (BL in FIGS. 2A to 3B) described above.

In the modified example, referring to FIG. 7A, the bit line described above (BL in FIGS. 2A to 3B) may be a bit line BLa including the first material layer 40 and the third material layer 46 stacked in order. In the bit line BLa, the first material layer 40 may be a metal-semiconductor compound layer for ohmic contact with the first source/drain region SD1 of the first region 9a, and the third material layer 46 may be a material layer to lower overall resistance of the bit line BLa. The third material layer 46 may be a metal layer having lower resistivity than that of the first material layer 40. The third material layer 46 may be in contact with the first material layer 40.

The third material layer 46 may be a material layer. The upper surface of the third material layer 46 may be in contact with the bit line capping layer 50. The upper surface of the third material layer 46 may be disposed at a level higher than a level of the upper surface 9u of the second region 9b, and the lower surface of the third material layer 46 may be disposed at a level lower than a level of the upper surface 9u of the second region 9b.

In the modified example, referring to FIG. 7B, the bit line (BLb in FIG. 7B) described above in FIG. 7A may be configured as a bit line BLb including a lower material layer 36, a first material layer 40 and a third material layer 46 stacked in order. In the bit line BLb, the lower material layer 36 may include doped silicon in contact with the first region 9a. Here, the doped silicon may be doped polysilicon or doped epitaxial silicon. The upper surface of the lower material layer 36 may be disposed at a level lower than a level of the upper surface 9u of the second region 9b. The first material layer 40 may be a metal-semiconductor compound layer for ohmic contact with the lower material layer 36, and the third material layer 46 may be a metal layer for lowering overall resistance of the bit line BLa. The third material layer 46 may be in contact with the first material layer 40.

In the modified example, referring to FIG. 7C, the bit line (BL in FIGS. 2A to 3B) described above in FIGS. 2A to 3B may be a bit line BLb including the first to third material layers 40, 43, and 46 described with reference to FIGS. 2A to 3B and a lower material layer 36 below the first material layer 40. In the bit line BLb, the lower material layer 36 may be the same as the lower material layer 36 described with reference to FIG. 7B.

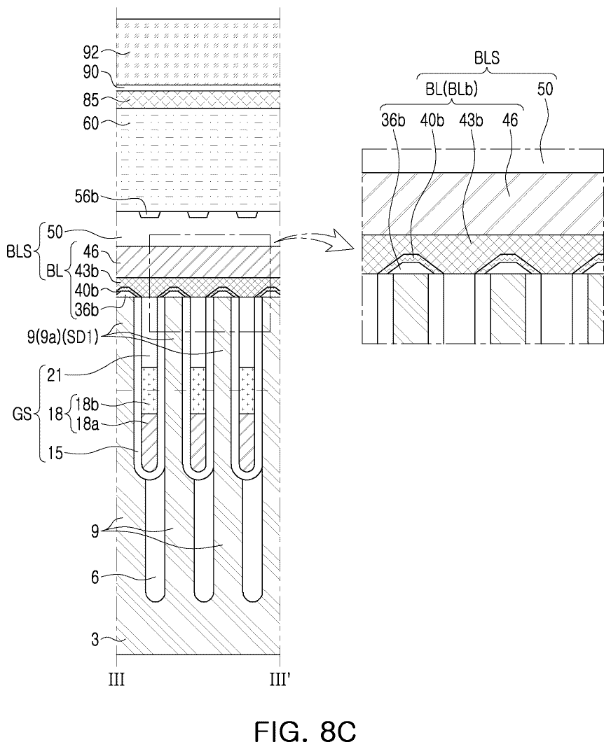

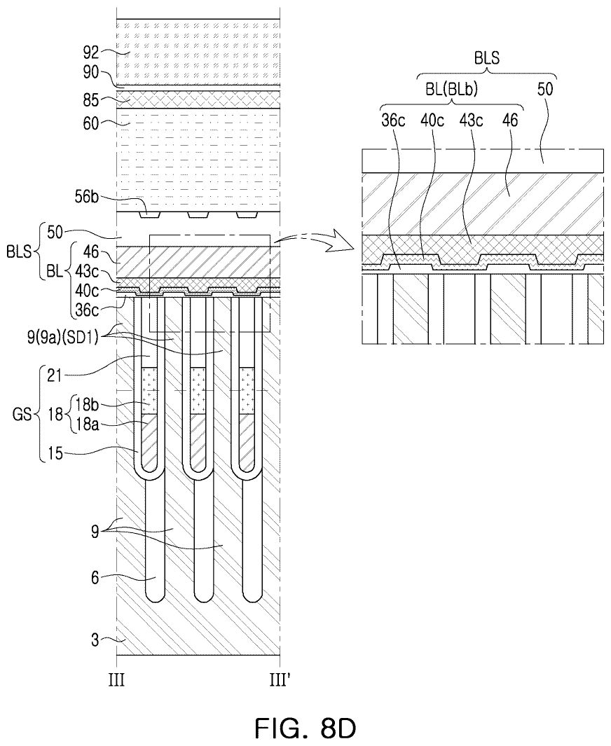

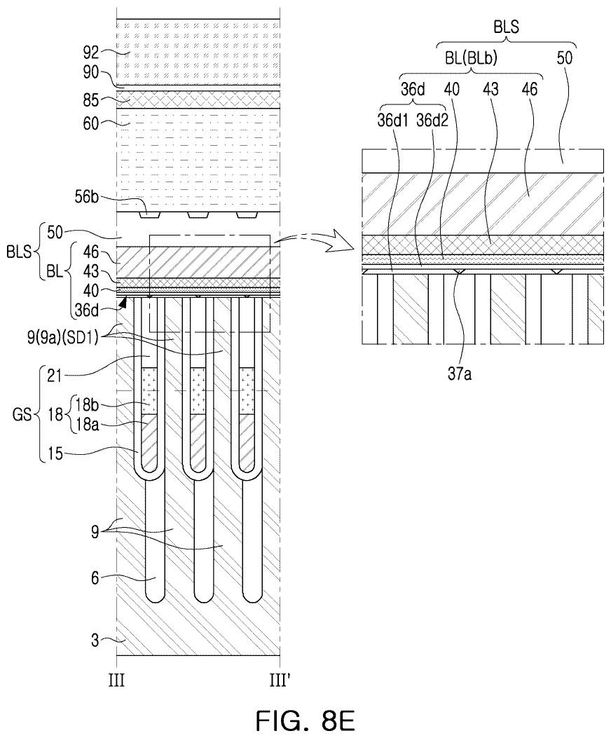

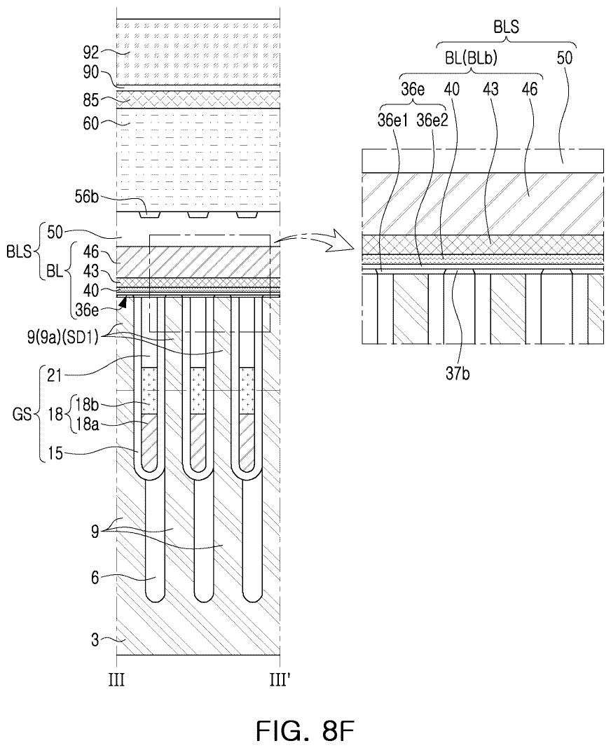

In the description below, various modified examples of the bit line (BL in FIGS. 2A to 3B) described above will be described with reference to FIGS. 8A, 8B, 8C, 8D, 8E, and 8F. FIGS. 8A, 8B, 8C, 8D, 8E, and 8F are cross-sectional diagrams taken along line III-III′ in FIG. 1A, cross-sectional diagrams illustrating various modified examples of the bit line (SP in FIGS. 2A to 3B) described above.

In the modified example, referring to FIGS. 1A and 8A, at the bit line BLb as in FIG. 7B or 7C, the lower material layer 36 may be in contact with the first regions 9a, may extend in the Y-direction, and may be in contact with upper surfaces of gate structures GS. Accordingly, the lower material layer 36 may have a line shape extending in the Y-direction.

In the modified example, referring to FIGS. 1A and 8B, in the bit line BLb as in FIG. 7B or 7C, the lower material layer 36 may be modified to lower material layers 36a in contact with the first regions 9b and spaced apart from each other in the Y-direction, the first material layer 40 may be modified to a first material layers 40a in contact with the lower material layers 36a and spaced apart from each other in the Y-direction, and the second material layer 43 may be modified to a second material layer 43a in contact with the first material layers 40a and extending to a region between the first material layers 40a and in contact with the upper surfaces of the gate structures GS. Each of the lower material layers 36b may have a quadrangular shape or a shape similar to a quadrangular shape.

In the modified example, referring to FIGS. 1A and 8C, in the bit line BLb as in FIG. 7B or 7C, the lower material layer 36 may be modified to lower material layers 36b in contact with the first regions 9b, spaced from each other in the Y-direction, having a triangle shape or a shape similar to a triangle shape, and the second material layer 43 may be modified to a second material layer 43b in contact with the first material layers 40b and extending to a region between the first material layers 40b and in contact with the upper surfaces of the gate structures GS.

In the modified example, referring to FIGS. 1A and 8D, in the bit line BLb as in FIG. 7B or 7C, the lower material layer 36 may be modified to a lower material layer 36c in contact with the first regions 9a, extending in the Y-direction, having a first thickness on the first regions 9a, and having a second thickness less than the first thickness on the gate structures GS, the first material layer 40 may be modified to a first material layer 40c in contact with the lower material layer 36c, and the second material layer 43 may be modified to a second material layer 43c in contact with the first material layers 40c.

In the modified example, referring to FIGS. 1A and 8E, in the bit line BLb as in FIG. 8A, the lower material layer 36 may be modified to a lower material layer 36d including a first lower material layer 36d1 having a side surface of a positive slope and a second lower material layer 36d2 on the first lower material layer 36d1. The first lower material layer 36d1 may include epitaxial silicon, and the second lower material layer 36d2 may include epitaxial silicon or polysilicon.

A void 37a having an upper width greater than a lower width may be disposed between the first lower material layers 36d1.

In the modified example, referring to FIGS. 1A and 8F, in the bit line BLb as in FIG. 8A, the lower material layer 36 may be modified to a lower material layer 36e including a first lower material layer 36e1 having a side surface of a negative slope and a second lower material layer 36e2 on the first lower material layer 36e1. The first lower material layer 36e1 may include epitaxial silicon, and the second lower material layer 36e2 may include epitaxial silicon or polysilicon. The first lower material layers 36e1 may be spaced apart from each other.

A void 37b having an upper width smaller than a lower width may be disposed between the first lower material layers 36e1.

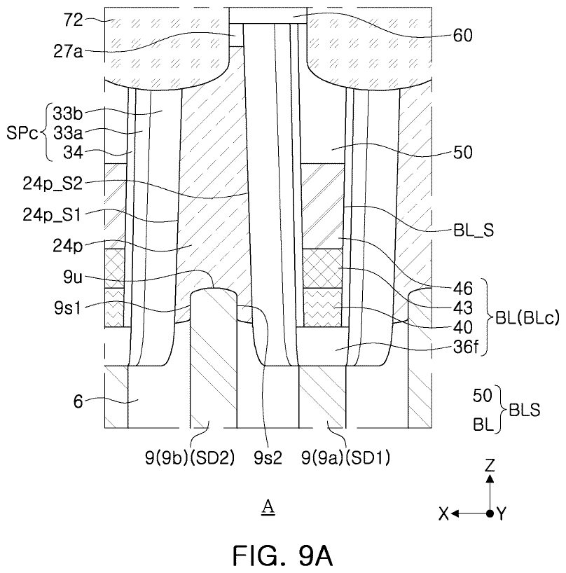

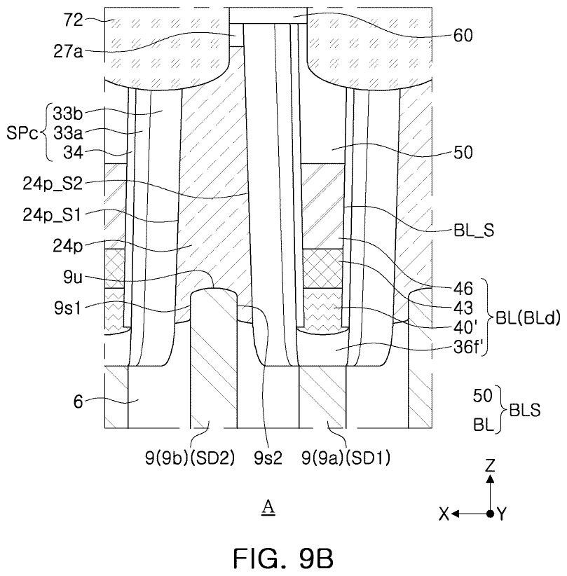

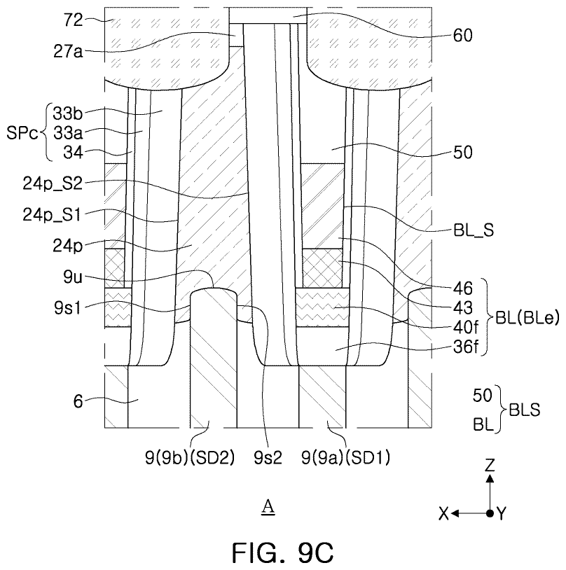

In the description below, various modified examples of the bit line (BL in FIGS. 2A to 3B) and the spacer structure (SP in FIGS. 2A and 2B) described above will be described with reference to FIGS. 9A, 9B and 9C. FIGS. 9A, 9B and 9C are enlarged diagrams corresponding to the enlarged diagram in FIG. 2b, diagrams illustrating various modified examples of the bit line (BL in FIGS. 2A to 3B) and the spacer structure (SP in FIGS. 2A and 2B) described above.

In the modified example, referring to FIG. 9A, the bit line (BL in FIGS. 2A to 3B) described above may be a bit line BLc including the first to third material layers 40, 43, and 46 described above and also the lower material layer 36f disposed below the first material layer 40.

In the bit line BLc, the lower material layer 36f may be in contact with the first region 9a, the width of the lower material layer 36f may be greater than the width of the first material layer 40, and the first to third material layers 40, 43, and 46 may have aligned side surfaces. The lower material layer 36f may include at least one of doped silicon, metal-semiconductor compound, metal-nitride, and metal.

The side surfaces of the first to third material layers 40, 43, and 46 may be aligned with the side surface of the bit line capping layer 50. The lower material layer 36f may have a side surface having a negative slope. The first to third material layers 40, 43, and 46 stacked in order may have a side surface having a negative slope.

The spacer structure (SP in FIGS. 2A and 2B) described above may be modified to a spacer structure SPc disposed on a portion of the upper surface of the lower material layer 36f and further including an internal spacer 34 covering side surfaces of the first to third material layers 40, 43, and 46 and the bit line capping layer 50. Accordingly, the spacer structure SPc may include the first and second spacer layers 33a and 33b as illustrated in FIGS. 2A and 2B, and the first spacer layer 33a may cover the side surface of the lower material layer 36f and the external side surface of the internal spacer 34. The internal spacer 34 may be disposed between the side surfaces of the first to third material layers 40, 43, and 46 and the bit line capping layer 50 and the first spacer layer 33a. The internal spacer 34 may be in contact with the upper surface of the lower material layer 36f. The internal spacer 34 may include at least one of silicon oxide, silicon nitride, SiOC, SiOCN, SiCN, and SiBN.

In the modified example, referring to FIG. 9B, in the bit line (BLc in FIG. 9A) and the spacer structure SPc described above in FIG. 9A, the bit line (BLc in FIG. 9A) may be modified to bit line BLd as in FIG. 9B. For example, in the bit line (BLc in FIG. 9A) described above in FIG. 9A, the first material layer 40 may be modified to first material layer 40′ extending to a region below the lower surface of the internal spacer 34, and the lower material layer 36f may be modified to a lower material layer 36f′ with a concave upper surface. Accordingly, the bit line BLd may include the lower material layer 36f′ and the first material layer 40′ along with the second and third material layers 43 and 46 described above.

In the modified example, referring to FIG. 9C, the bit lines (BL in FIGS. 2A to 3B) described above may be a bit line BLe including lower material layer 36f and first material layer 40f stacked in order, and the second material layer 43 and the third material layer 46 stacked in order on the first material layer 40f.

In the bit line BLe, the lower material layer 36f may be in contact with the first region 9a, the lower material layer 36f and the first material layer 40f may have aligned side surfaces, and the second material layer 43 and the third material layer 46 may have aligned side surfaces. A width of the first material layer 40f may be greater than a width of the second material layer 43.

The side surfaces of the lower material layer 36f and the first material layer 40f stacked in order may have a negative slope, and the side surfaces of the second material layer 43 and the third material layer 46 stacked in order may have a negative slope.

The spacer structure (SP in FIGS. 2A and 2B) described above may be modified to a spacer structure SPc disposed on a portion of the upper surface of the first material layer 40f and further including an internal spacer 34 covering side surfaces of the second and third material layers 43, 46 and the bit line capping layer 50. Accordingly, the spacer structure SPc may include the first and second spacer layers 33a and 33b as illustrated in FIGS. 2A and 2B, and the first spacer layer 33a may cover the side surfaces of the lower material layer 36f and the first material layer 40f and the external side surface of the internal spacer 34. The internal spacer 34 may be disposed between the side surfaces of the second and third 3 material layers 43 and 46 and the bit line capping layer 50 and the first spacer layer 33a. The internal spacer 34 may be in contact with the upper surface of the first material layer 40f.

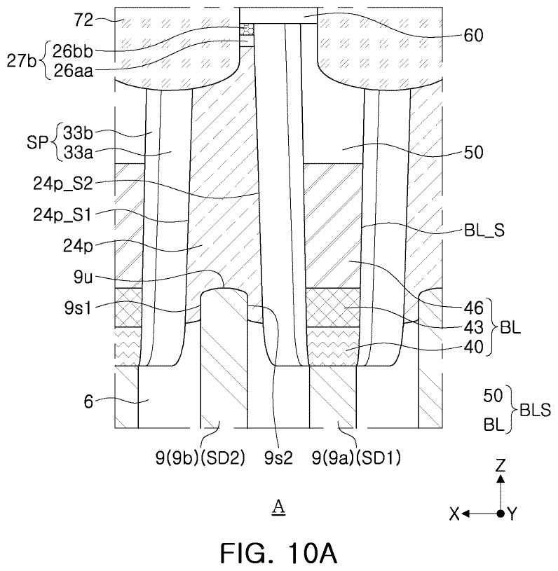

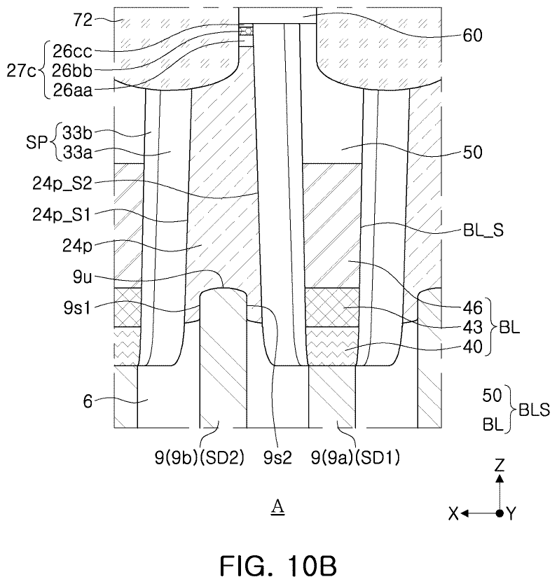

In the description below, various modified examples of the insulating buffer pattern (27a in FIGS. 2A to 3B) described above will be described with reference to FIGS. 10A and 10B. FIGS. 10A and 10B are enlarged diagrams corresponding to the enlarged diagram in FIG. 2B, diagrams illustrating various modified examples of the insulating buffer pattern (27a in FIGS. 2A to 3B) described above.

In the modified example, referring to FIG. 10A, the insulating buffer pattern (27a in FIGS. 2A to 3B) described above may be modified to an insulating buffer pattern 27b, including a first buffer layer 26aa and a second buffer layer 26bb stacked in sequence. The first buffer layer 26aa and the second buffer layer 26bb may be formed of different insulating materials. The first and second buffer layers 26aa and 266b may include an insulating material selected from among silicon oxide, silicon nitride, SiOC, SiOCN and metal oxide. For example, the first buffer layer 26aa may include silicon oxide, SiOC, or SiOCN, and the second buffer layer 26bb may include silicon nitride or metal oxide.

In the modified example, referring to FIG. 10B, the insulating buffer pattern described above (27a in FIG. 2A to FIG. 3B) may be modified to an insulating buffer pattern 27c including a first buffer layer 26aa, a second buffer layer 26bb and a third buffer layer 26cc stacked in order. The first, second, and third buffer layers 26aa, 266b, and 26cc may include an insulating material selected from among silicon oxide, silicon nitride, SiOC, SiOCN, and metal oxide. For example, the first buffer layer 26aa may include silicon oxide, SiOC, or SiOCN, the second buffer layer 26bb may include metal oxide, and the third buffer layer 26cc may include silicon nitride.

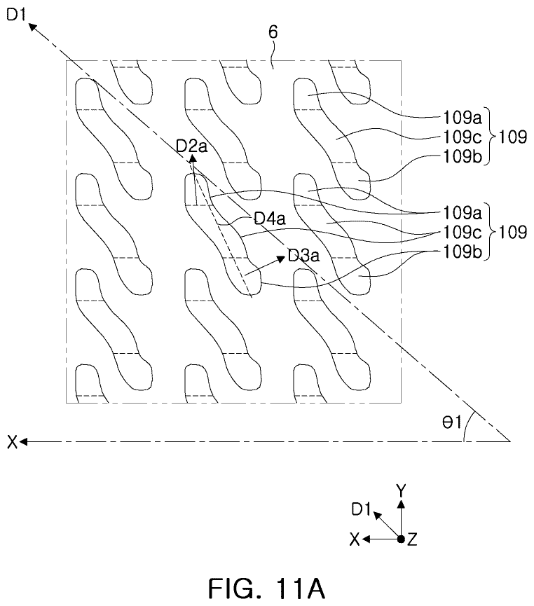

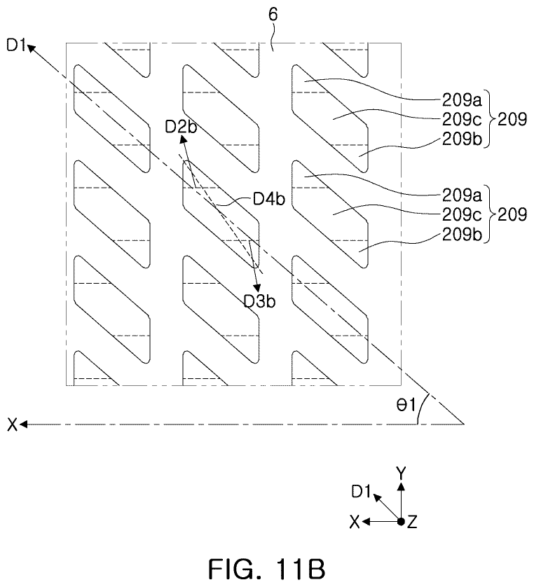

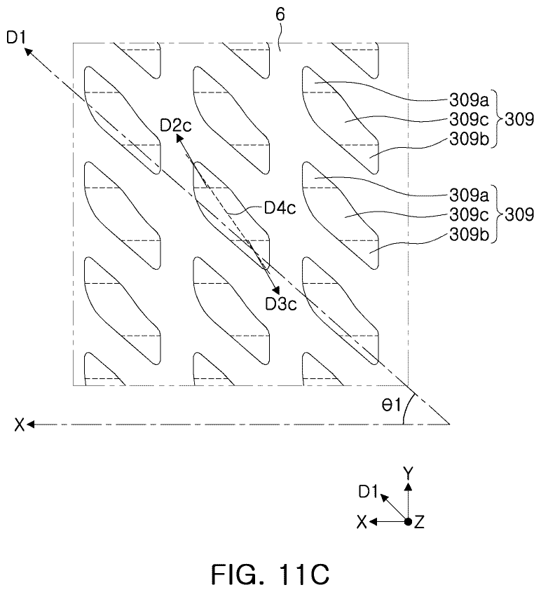

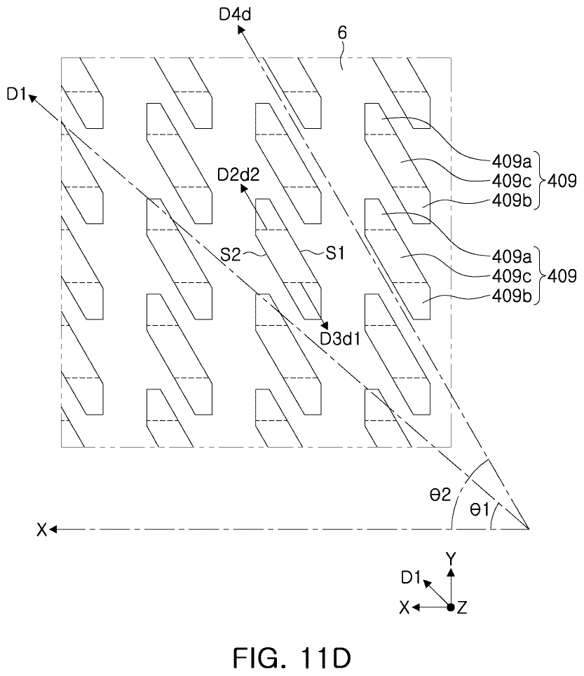

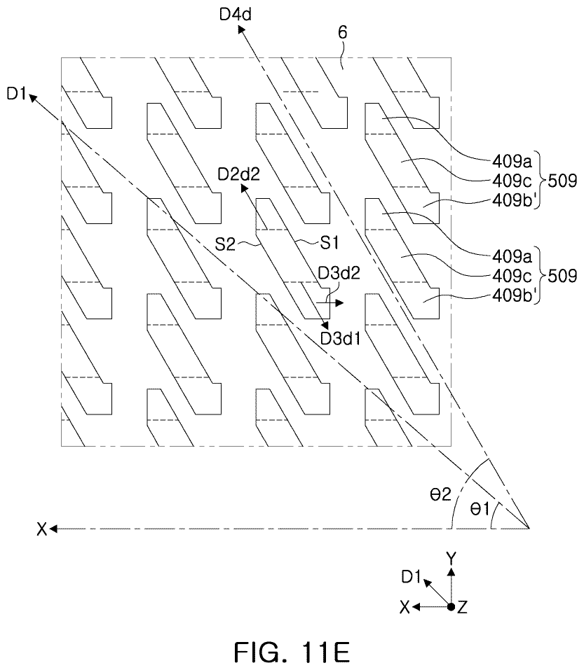

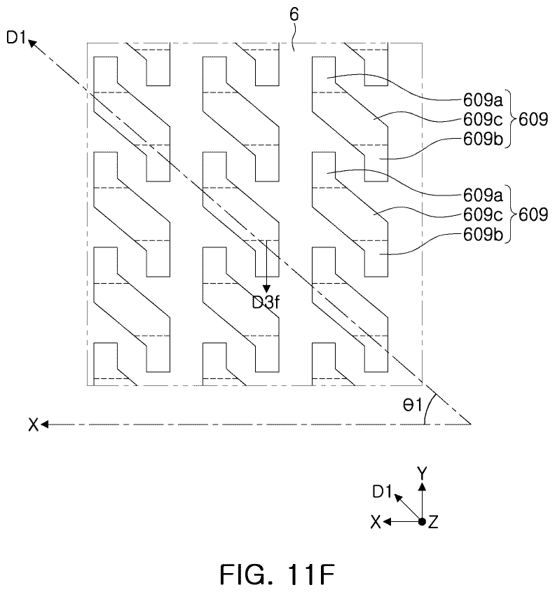

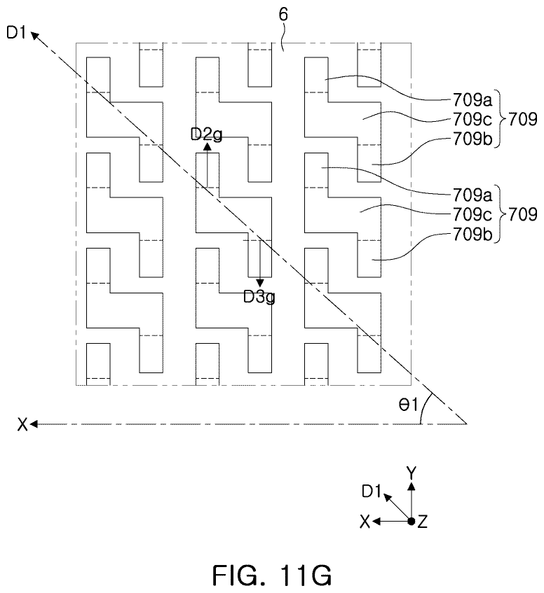

In the description below, various modified examples of the planar shape of the active regions (9 in FIGS. 1A to 1D) described above will be described with reference to FIGS. 11A to 11G. FIGS. 11A to 11G are diagrams corresponding to the diagram in FIG. 1C, diagrams illustrating various modified examples of the planar shape of the active regions (9 in FIGS. 1A to 1D) described above. Hereinafter, “first region,” “second region,” and “third region” in various active regions described below may be provided to describe modified example of the planar shape of the first region 9a, the second region 9b and the third region 9c of the active regions (9 in FIG. 1A to FIG. 1D) described above. Accordingly, “first region”, “second region”, and “third region” in various active regions described below may be understood from the description of the first region 9a, the second region 9b and the third region 9c of the active regions (9 in FIGS. 1A to 1D) described above unless otherwise indicated. Also, the planar shapes of various active regions describing FIGS. 11A to 11G may be described on the basis of the drawings.

In the modified example, referring to FIG. 11A, the active regions (9 in FIGS. 1A to 1D) described above may be replaced with active regions 109 having the same planar shape as in FIG. 11A. For example, the active regions 109 may be arranged in the X-direction and the D1 direction as described with reference to FIGS. 1A to 1D. Each of the active regions 109 may include a first region 109a and a second region 109b spaced apart from each other, and a third region 109c disposed between the first and second regions 109a and 109b. The active region 109 may have a major axis D4a inclined with respect to the D1 direction.

The third region 109c may extend in an inclined direction with respect to the X-direction and may be curved to one side. When viewed with respect to the third region 109c, the first region 109a may be bent from the third region 109c and may extend in the upward direction D2, and the second region 109b may include a first portion extending from the third region 103c in the lower right direction D3a and a second portion protruding from the first a portion in the upper right direction D3a2.

In the modified example, referring to FIG. 11B, the active regions (9 in FIGS. 1A to 1D) described above may be replaced with active regions 209 having the same planar shape as in FIG. 11B. For example, the active regions 209 may be arranged in the X-direction and the D1 direction as described with reference to FIGS. 1A to 1D.

The active region 209 may have a rectangular shape having a pair of side surfaces extending in the Y-direction and a pair of side surfaces extending in the D1 direction.

Each of the active regions 209 may include a first region 209a and a second region 209b spaced apart from each other, and a third region 209c disposed between the first and second regions 209a and 209b. The active region 209 may have a major axis D4b inclined with respect to the D1 direction.

The first region 209a may have a triangular shape extending from the third region 209c in the upper left direction D2b and having a width decreasing in the direction D2b, and the second region may have a triangular shape extending from the third region 209c in the lower right direction D3b and having a width decreasing in the direction D3b.

In the modified example, referring to FIG. 11C, the active regions (9 in FIGS. 1A to 1D) described above may be replaced with active regions 309 having the same planar shape as in FIG. 11C. For example, the active regions 309 may be arranged in the X-direction and the D1 direction as described with reference to FIGS. 1A to 1D.

Each of the active regions 309 may include a first region 309a and a second region 309b spaced apart from each other, and a third region 309c between the first and second regions 309a and 309b. The active region 309 may have a major axis D4c inclined with respect to the D1 direction.

The first region 309a may have a triangular shape extending from the third region 309c in the upper left direction D2c and having a width decreasing in the direction D2c, and the second region 309b may have a triangular shape extending from the third region 309c in the lower right direction D3c and having a width decreasing in the direction D3c.

The third region 309c may have a shape of which a width may gradually increase in the direction from the second region 309b toward the first region 309a and decreasing in a region adjacent to the first region 309a. The third region 309c may have asymmetric side surfaces facing each other between the first region 309a and the second region 309b, and among these asymmetric side surfaces, the side surface disposed on the right side may be convex toward the right side.

In the modified example, referring to FIG. 11D, the active regions (9 in FIGS. 1A to 1D) described above may be replaced with active regions 409 having the same planar shape as in FIG. 11D. For example, the active regions 409 may be arranged in the X-direction and the D1 direction as described with reference to FIGS. 1A to 1D.

Each of the active regions 409 may include a first region 409a and a second region 409b spaced apart from each other, and a third region 409c disposed between the first and second regions 409a and 409b. The active region 409 may have a major axis extending in the D4d direction inclined at a second angle θ2 with the X-direction. The second angle θ2 may be from about 55 degrees to about 70 degrees. The third region 409c may have a constant width and may extend in the D4d direction.

The third region 409c may have a first side surface S1 and a second side surface S2 parallel to the D4d direction and facing each other. Among the first and second side surfaces S1 and S2, the right side surface may be the first side surface S1, and the left side surface may be the second side surface S2.

The first region 409a may have a side surface extending continuously from the first side surface S1 in the direction D2d2parallel to the direction D4d and a side surface curved upwardly from the second side surface S2 and extending in a direction parallel to the Y-direction. Accordingly, the first region 409a may extend from the third region 409c while a width thereof may decrease.

The second region 409b my have a side surface extending continuously from the second side surface S2 in the direction D3d1parallel to the direction D4d and a side surface bent downwardly from the first side surface S1 and extending in a direction parallel to the Y-direction. Accordingly, the second region 409b may extend from the third region 409c while a width thereof may decrease.

In the modified example, referring to FIG. 11E, the second region (409b in FIG. 11D) illustrated in FIG. 11D may be modified to a second region 409b′ extending from the second region (409b in FIG. 11D) described in FIG. 11D in the direction D3d2 parallel to the X-direction and further including a portion protruding to the right side from the second region (409d in FIG. 11D). Accordingly, the active region 409 described with reference to FIG. 11D may be replaced with an active region 509 including the second region 409b′ as illustrated in FIG. 11E along with the first region 409a and the third region 409c as illustrated in FIG. 11D.

In the modified example, referring to FIG. 11F, the active regions (9 in FIGS. 1A to 1D) described above may be replaced with the active regions 609 having the same planar shape as in FIG. 11F. For example, the active regions 609 may be arranged in the X-direction and the D1 direction as described with reference to FIGS. 1A to 1D.

Each of the active regions 609 may include a first region 609a and a second region 609b spaced apart from each other, and a third region 609c disposed between the first and second regions 609a and 609b. The third region 609c may extend in the D1 direction, the first region 609a may be bent from the third region 609c and may extend in an upward direction parallel to the Y-direction, and the second region 609b may be curved from the third region 609c and may extend in the direction D3f parallel to the Y-direction and directed downwardly.

In the modified example, referring to FIG. 11G, the previously described active regions (9 in FIGS. 1A to 1D) may be replaced with active regions 709 having the same planar shape as in FIG. 11G. For example, the active regions 709 may be arranged in the X-direction and the D1 direction as described with reference to FIGS. 1A to 1D.

Each of the active regions 709 may include a first region 709a and a second region 709b spaced apart from each other, and a third region 709c disposed between the first and second regions 709a and 709b. The third region 709c may be bent from the left side of the third region 709c and may extend in the direction D2g parallel to the Y-direction and directed upwardly, and the second region 709b may be bent from the right side of the third region 609c and may extend in the direction D3g parallel to the Y-direction and directed downwardly.

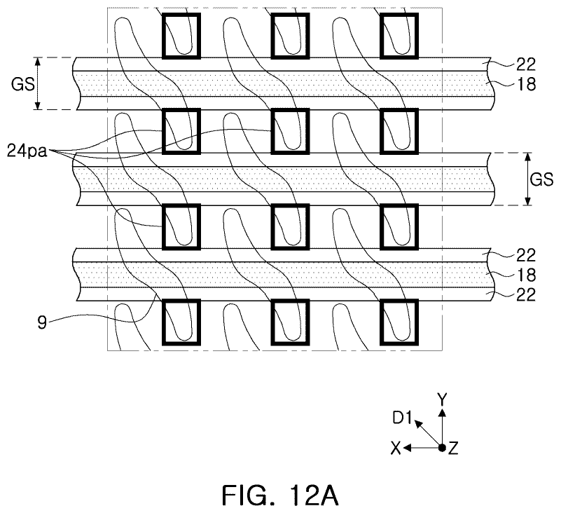

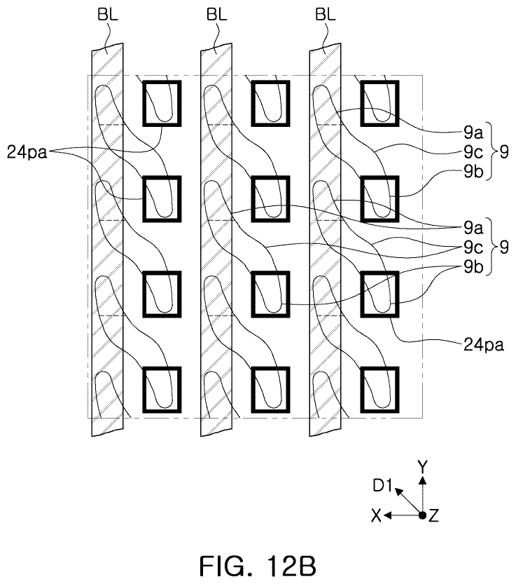

In the description below, a modified example of the pad patterns (24p in FIGS. 1A, 1B, and 1C) described above will be described with reference to FIGS. 12A and 12B. FIG. 12A is a diagram corresponding to FIG. 1B illustrating a modified example of pad patterns 24p in FIG. 1B, and FIG. 12B is a diagram corresponding to FIG. 1D illustrating a modified example of pad patterns 24p in FIG. 1D.

In the modified example, referring to FIGS. 12A and 12B, the pad patterns described above (24p in FIGS. 1A, 1B, and 1C) may be modified to pad patterns 24pa having side surfaces aligned with the side surfaces of the gate structures GS. Accordingly, the distance between the pad patterns 24pa in the Y-direction may be substantially equal to the width of the gate structure GS.

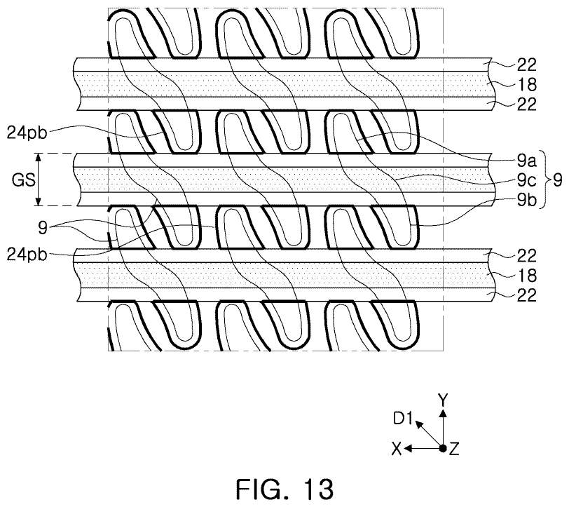

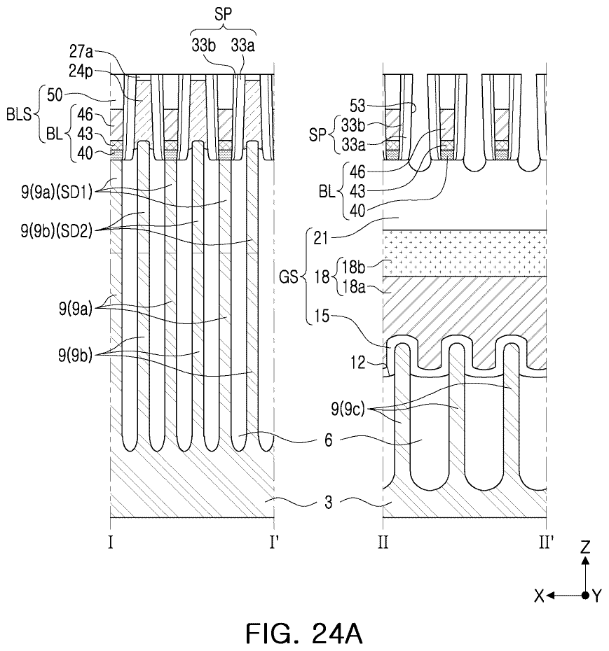

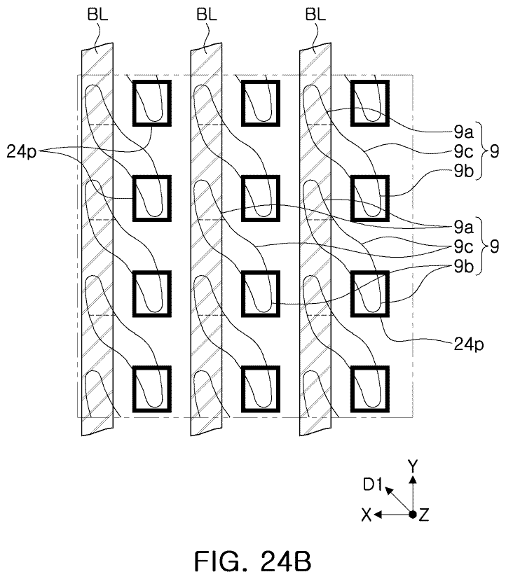

In the description below, a modified example of the pad patterns (24p in FIGS. 1A, 1B, and 1C and 24pa in FIGS. 12A and 12B) described above will be described with reference to FIG. 13. FIG. 12A is a diagram corresponding to FIG. 12A illustrating a modified example of the pad patterns described above (24p in FIGS. 1A, 1B, 1C and 24pa in FIGS. 12A and 12B).

In the modified example, referring to FIG. 13, the pad patterns described above (24p in FIGS. 1A, 1B, and 1C and 24pa in FIGS. 12A and 12B) may have a rectangular shape, but in an example embodiment thereof is not limited thereto, and the pad patterns may be modified to pad patterns 24pb having a shape as in FIG. 13. For example, side surfaces opposing each other in the X-direction of the pad patterns 24pb may have substantially the same shape as that of the side surfaces of the first and second regions 9a and 9b of the active regions 9. When viewed from one of the gate structures GS as a center, each of the 24 pb pad patterns may have a shape having a width decreasing in the Y-direction away from the gate structure GS.

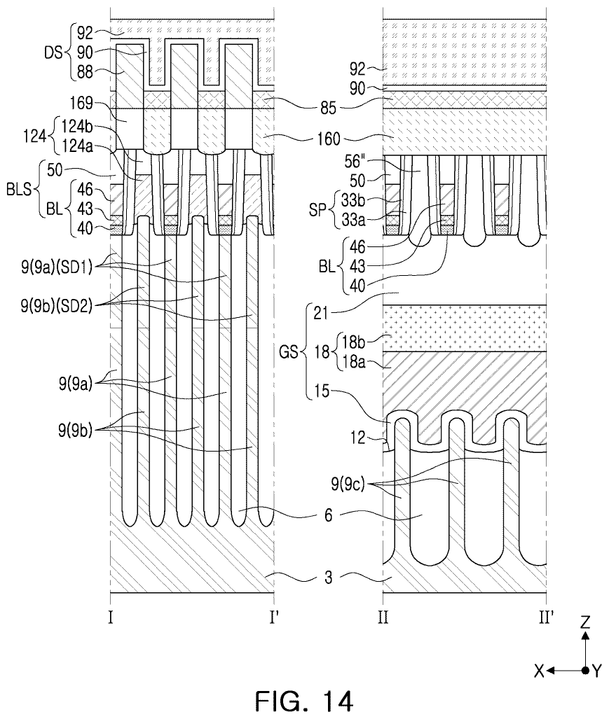

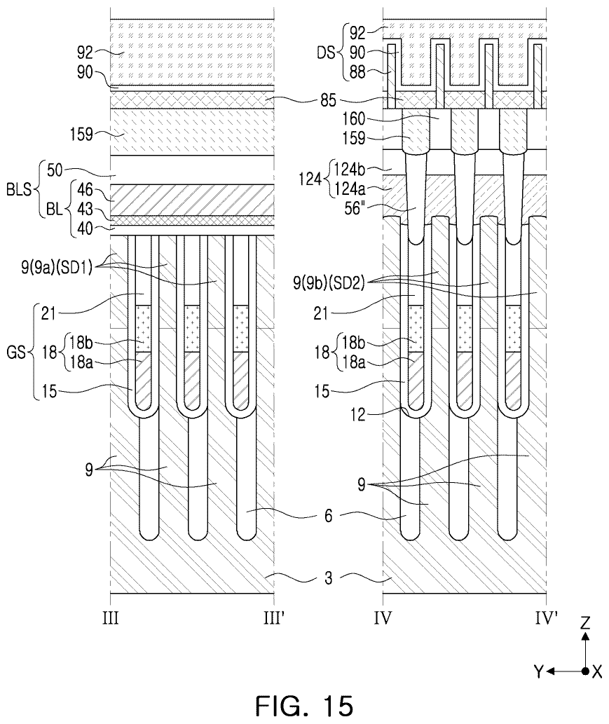

In the description below, a modified example of a semiconductor device according to an example embodiment will be described with reference to FIGS. 14 and 15. FIG. 14 is a cross-sectional diagram illustrating regions taken along lines I-I′ and II-II′ in FIG. 1A, and FIG. 15 is a cross-sectional diagram illustrating regions taken along lines III-III′ and IV-IV′ in FIG. 1A.

In the modified example, referring to FIGS. 14 and 15, the pad pattern described above (24p in FIGS. 2A to 3B) may be replaced with pad pattern 124 including the first layer 124a and the second layer 124b stacked in sequence. The first layer 124a may include a doped silicon layer, and the second layer 124b may include at least one of a metal-semiconductor compound layer, a metal nitride layer, and a metal layer. The doped silicon layer may include at least one of doped polysilicon and doped epitaxial silicon. The upper surface of the pad pattern 124 may be coplanar with the upper surface of the bit line structure BLS and the upper surface of the spacer structure SP.

The contact structures (69 in FIGS. 2A to 3B) and the interlayer insulating layer (60 in FIGS. 2A to 3B) described above may be replaced with the contact structure 169 and interlayer insulating layer 160 as illustrated in FIGS. 14 and 15, respectively.

The contact structure 169 may have a flat lower surface. The lower surface of the contact structure 169 may be in contact with the upper surface of the pad pattern 124, the upper surface of the bit line structure BLS, and the upper surface of the spacer structure SP.

The interlayer insulating layer 160 may have a side surface coplanar with the upper surface of the contact structure 169. The interlayer insulating layer 160 may surround the side surface of the contact structure 169, may extends downwardly, and may be in contact with the pad pattern 124, the bit line structure BLS, and the spacer structure SP. The lower surface of the interlayer insulating layer 160 may be disposed at a level lower than a level of the lower surface of the contact structure 169.

The insulating separation patterns (56 in FIGS. 2A to 3B) described above may be modified to insulating separation patterns 56″ in which the second separation portions (56b in FIGS. 2A to 3B) may not be provided. The upper surface of the insulating separation patterns 56″ and the upper surface of the spacer structures SP may be coplanar with each other below the lower surface of the interlayer insulating layer 160.

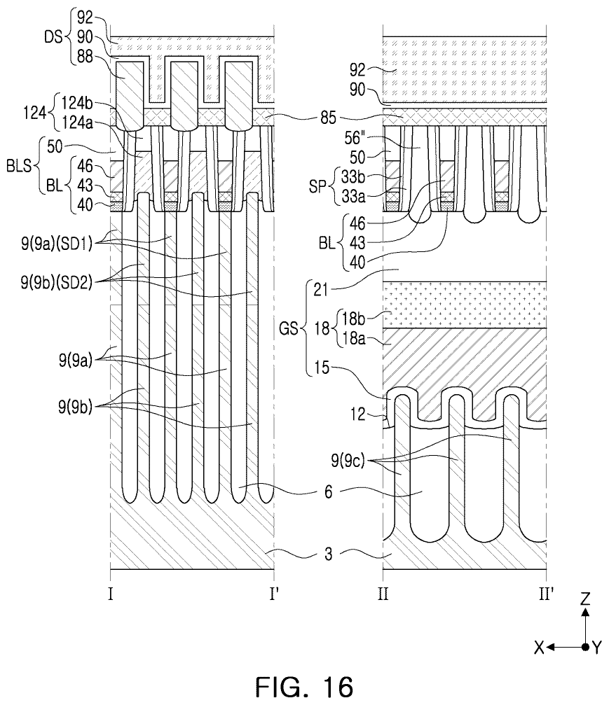

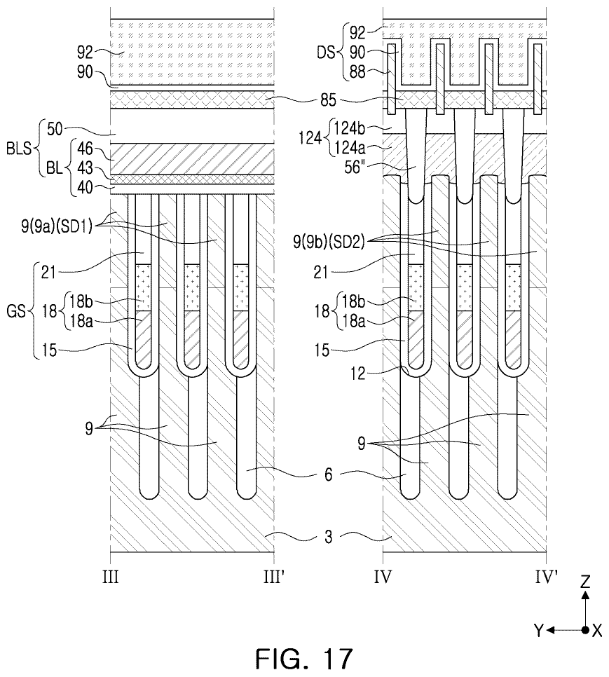

In the description below, a modified example of a semiconductor device according to an example embodiment will be described with reference to FIGS. 16 and 17. FIG. 16 is a cross-sectional diagram illustrating regions taken along lines I-I′ and II-II′ in FIG. 1A, and FIG. 17 is a cross-sectional diagram illustrating regions taken along lines III-III′ and IV-IV′ in FIG. 1A.

In the modified example, referring to FIGS. 16 and 17, in the semiconductor device described with reference to FIGS. 14 and 15, the interlayer insulating layer 160 and the contact structure 169 may not be provided. The etch stop layer 85 may be in contact with the upper surfaces of the bit line structure BLS, the pad patterns 124, the spacer structures SP, and the insulating separation patterns 56″. The first electrodes 88 of the data storage structure DS may penetrate through the etch stop layer 85 and may be in direct contact with the pad patterns 124.

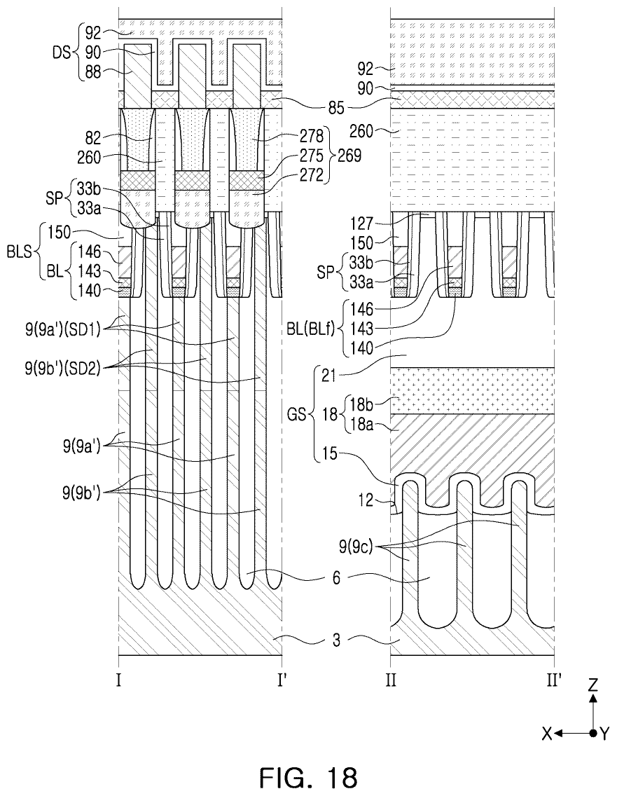

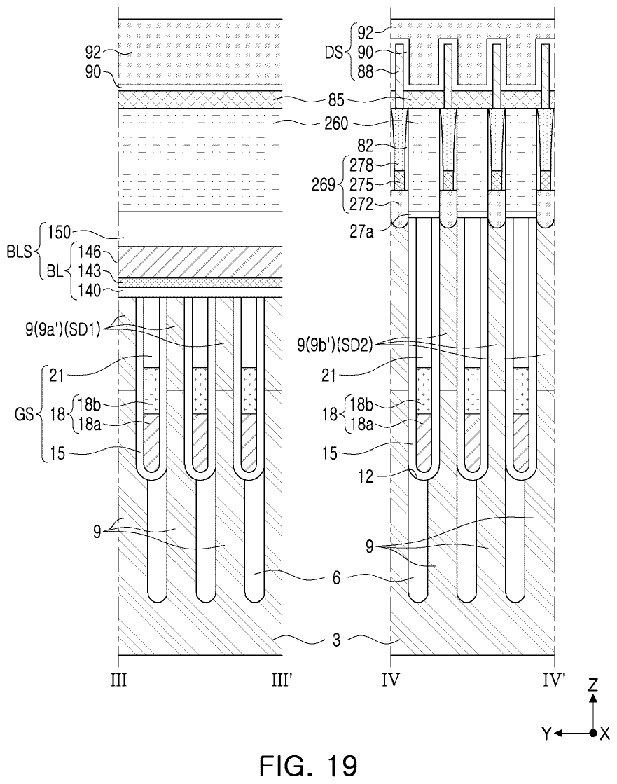

In the description below, a modified example of a semiconductor device according to an example embodiment will be described with reference to FIGS. 18 and 19. FIG. 18 is a cross-sectional diagram illustrating regions taken along lines I-I′ and II-II′ in FIG. 1A, and FIG. 19 is a cross-sectional diagram illustrating regions taken along lines III-III′ and IV-IV′ in FIG. 1A.

In the modified example, referring to FIGS. 16 and 17, the first regions 9a and the second regions 9b of the active regions (9 in FIGS. 2A to 3B) described above may be modified to first regions 9a and second regions 9b as in FIGS. 18 and 19. For example, in the active regions 9, a difference in levels between the upper surfaces of the first regions 9a′ and the upper surfaces of the second regions 9b′ may be greater than the distance between the upper and lower surfaces of each of the bit lines BL.

The first to third material layers (40, 43, and 46 in FIGS. 2A to 3B) described above, which are stacked in order and included in the bit lines BL, may be modified to first to third material layers 140, 143, 146 stacked in order as shown in FIGS. 18 and 19 and disposed at a level lower than a level of the upper surfaces of the second regions 9b′. The upper surfaces of the bit lines BL may be disposed at a level lower than a level of the upper surfaces of the bit line capping layer 21.

The bit line capping layer (50 in FIGS. 2A to 3B) described above may be modified to bit line capping layer 150 having an upper surface disposed on substantially the same level as a level of the upper surface of the second regions 9b′. Accordingly, the bit line structure BLS including the bit lines BL and the bit line capping layer 150 may have an upper surface disposed on substantially the same level as a level of the upper surface of the second regions 9b′. The bit line structures BLS may be disposed between the second regions 9b′ and may extend into the gate capping layer 21.

The spacer structures SP disposed on the side surfaces of the bit line structures BLS, described above, may be disposed between the side surfaces of the bit line structures BLS and the second regions 9b′, and between the side surfaces of the bit line structures BLS and the gate capping layer 21.

The insulating buffer patterns 27a′ described above may be replaced with insulating buffer patterns 127 disposed on the second regions 9b′, the spacer structure SP, and the gate capping layer 21.

The pad patterns described above (24p in FIGS. 2A to 3B) may not be provided, and the contact structures 69 described above may be directly connected to the second regions 9b′.

In the description below, a method of forming a semiconductor device according to an example embodiment will be described. Here, in describing the method of forming a semiconductor device, since the material and shape (or structure) of the components described above have been described above, a detailed description of the material and shape (or structure) of the components will not be provided.

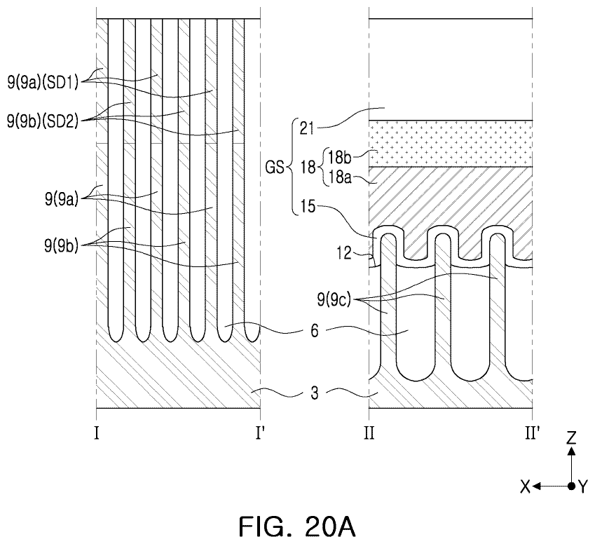

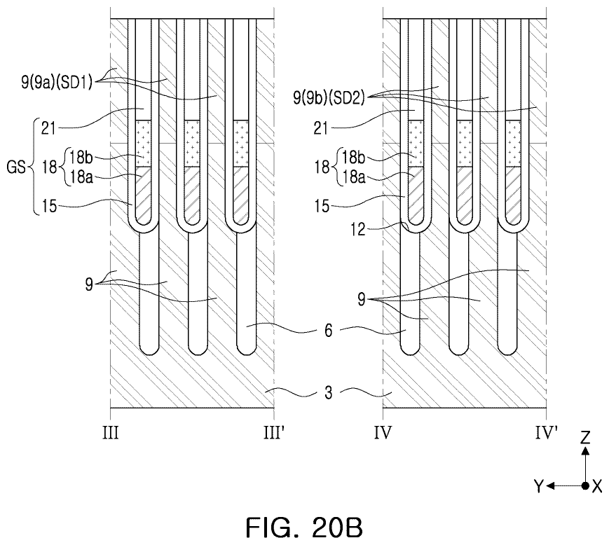

First, an example embodiment of a method of forming a semiconductor device according to an example embodiment will be described with reference to FIGS. 20A to 25B. In FIGS. 20A to 25B, FIGS. 20A, 21A, 22A, 23A, 24A, and 25A are cross-sectional diagrams illustrating regions taken along lines I-I′ and II-II′ in FIG. 1A, and FIGS. 20b, 21b, 22b, 23b, 24b, and 25b are cross-sectional diagrams illustrating regions taken along lines III-III′ and lines IV-IV′ in FIG. 1A.

Referring to FIGS. 1A to 1D, and FIGS. 20A and 20B, a device isolation layer 6 defining active regions 9 may be formed on a substrate 3. The device isolation layer 6 may be formed using a trench device isolation process.

Gate trenches 12 intersecting the active regions 9 and extending into the device isolation layer 6 may be formed. The gate structures GS may be formed in the gate trenches 12. Each of the gate structures GS may have a line shape extending in the X-direction.

The forming the gate structures GS may include forming a gate dielectric layer 15 on the internal wall of the gate trench 12, forming a gate electrode 18 partially filling the gate trench 12 on the gate dielectric layer 15, and forming a gate capping layer 21 on the gate electrode 18.

As previously described with reference to FIGS. 1A to 3B, each of the active regions 9 may include a first region 9a and a second region 9b isolated from each other by one of the gate structures GS and a third region 9c disposed below the gate structure GS.

The upper surfaces of the active regions 9, the gate structures GS and the device isolation layer 6 may be coplanar with each other.

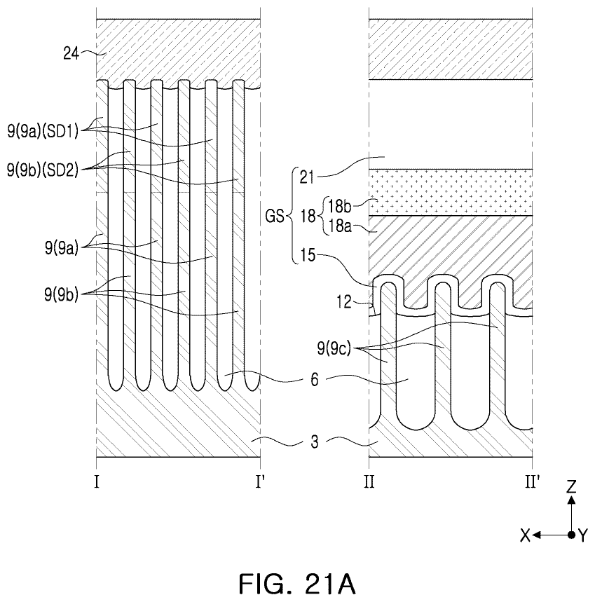

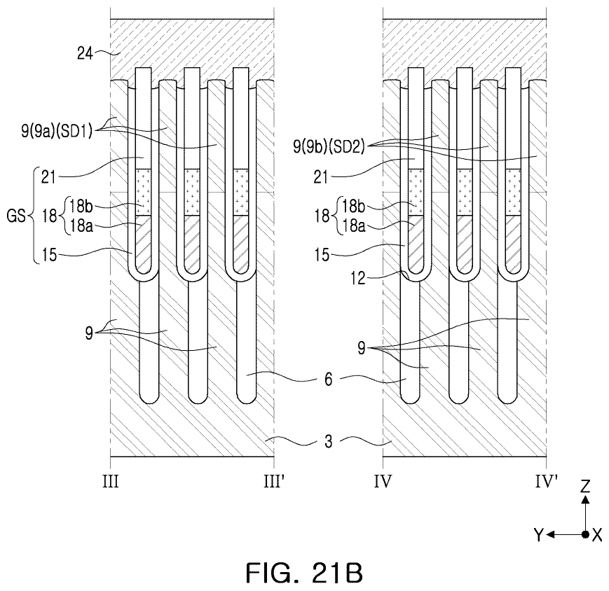

Referring to FIGS. 1A to 1D, and FIGS. 21A and 21B, the gate dielectric layers 15 and the device isolation layer 6 of the gate structures GS may be partially etched such that upper regions of the side surfaces of the first and second regions 9a and 9b of the active region 9 may be exposed.

Subsequently, pad material layer 24 may be formed. The pad material layer 24 may be in contact with the upper surfaces of the first and second regions 9a and 9b and the upper regions of the side surfaces of the first and second regions 9a and 9b.

In an example, the pad material layer 24 may be formed of doped silicon. The doped silicon may include at least one of doped polysilicon formed using a deposition process or doped epitaxial silicon formed using a selective epitaxial growth process.

In another example, the pad material layer 24 may be formed to further include at least one of a metal-semiconductor compound, a metal nitride, and a metal along with doped silicon.

In another example, the pad material layer 24 may be formed to include at least one of a metal nitride layer and a metal layer along with a metal-semiconductor compound layer in contact with the first and second regions 9a and 9b.

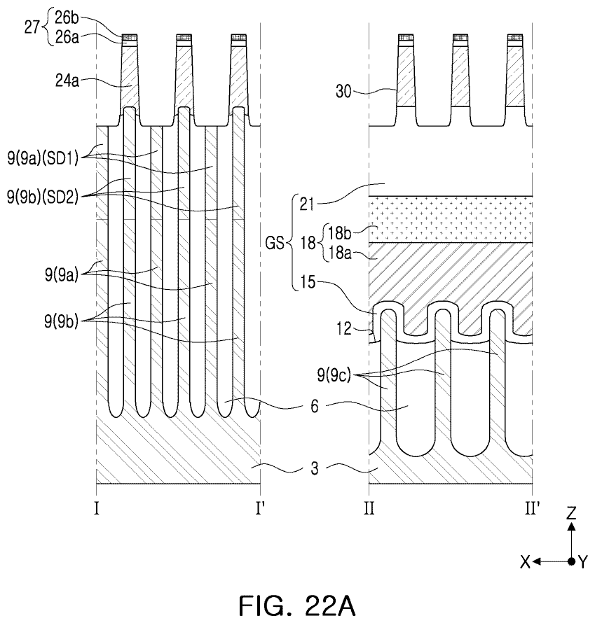

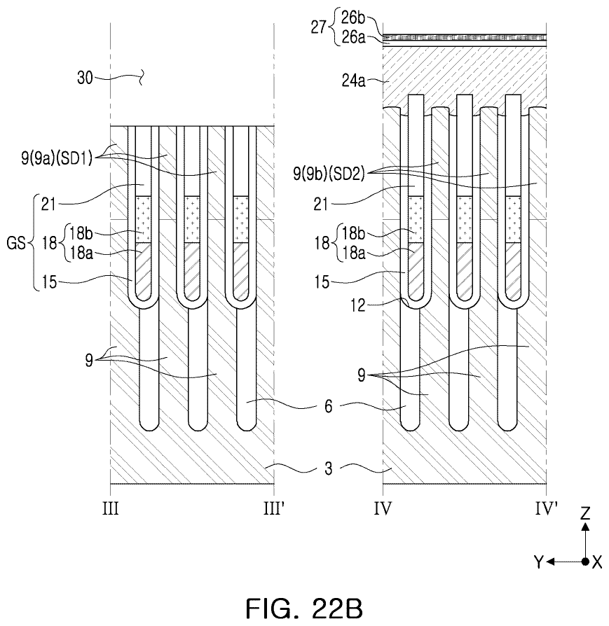

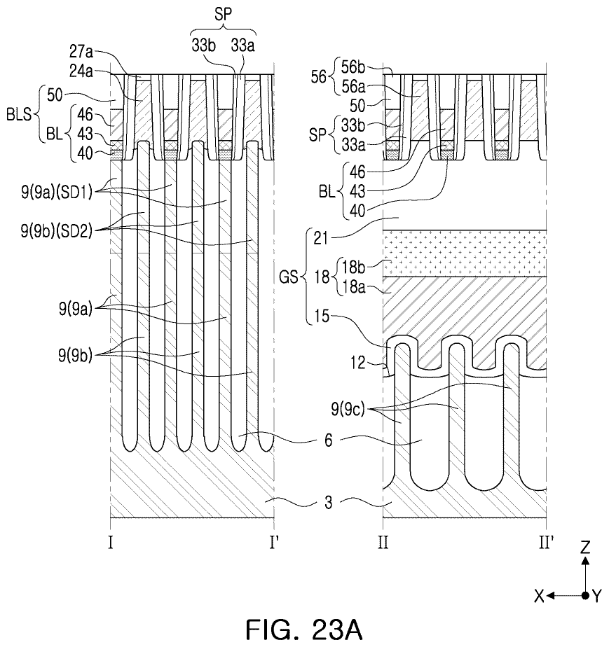

Referring to FIGS. 1A to 1D, and FIGS. 22A and 22B, preliminary pad patterns 24a may be formed by patterning the pad material layer 24. Each of the preliminary pad patterns 24a may have a line shape extending in the Y-direction.

The forming the preliminary pad patterns 24a having the bit line trenches 30 may include forming a line-shaped preliminary buffer layer 27 extending in the Y-direction on the pad material layer 24, exposing the first regions 9a while forming the preliminary pad patterns 24 by etching the pad material layer 24 through an etching process using the preliminary buffer layer 27 as an etch mask, and partially etching the exposed first regions 9a. Accordingly, the first regions 9a may be formed to have upper surfaces disposed at a level lower than a level of the upper surfaces of the second regions 9b. Void spaces exposing the first regions 9a between the preliminary patterns 24a may be defined as bit line trenches 30. The preliminary buffer layer 27 may include a first layer 26a and a second layer 26b stacked in order.

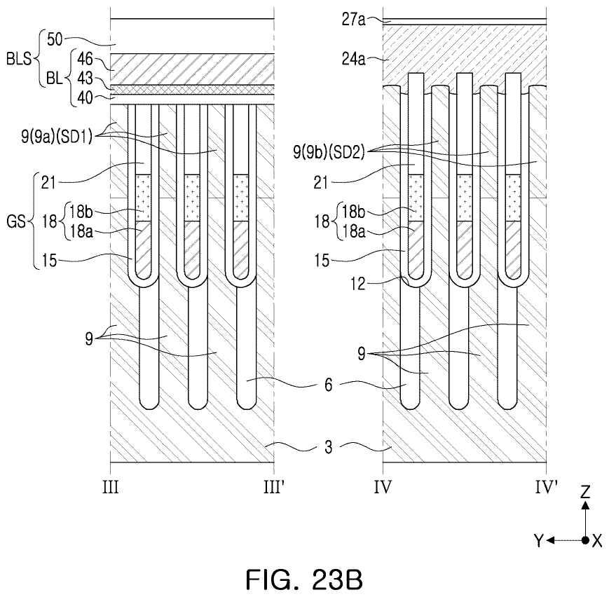

Referring to FIGS. 1A to 1D, and FIGS. 23A and 23B, a spacer process may be performed to form spacer structures SP on the side surfaces of the bit line trenches 30. The forming the spacer structures SP may include forming a first spacer material layer and a second spacer material layer in order, and forming first and second spacer layers 33a and 33b remaining on the side surfaces of the bit line trenches 30 by anisotropically etching the first and second spacer material layers.

Thereafter, bit line structures BLS may be formed. The forming the bit line structures BLS may include forming bit lines BL partially filling the bit line trenches 30 and forming bit line capping layers 50 on the bit lines BL.

The forming the bit lines BL may include forming first material layers 40a in contact with the first regions 9a, and forming second material layers 43 and third material layers 46 in order on the first material layers 40a.

The forming the bit line capping layers 50 may include forming an insulating material layer filling the bit line trenches 30 on the bit lines BL and covering the preliminary buffer layer 27, and planarizing the insulating material layer until the first layer 26a of the preliminary buffer layer 27 is exposed.

While forming the bit line capping layers 50, the second layer 26b of the preliminary buffer layer 27 may be removed, and at least a portion of the first layer 26a may remain. The first layer 26a other in the preliminary buffer layer 27 may be defined as a buffer layer 27a.

Referring to FIGS. 1A to 1D and FIGS. 24A and 24B, the buffer layer 27a and the preliminary pad patterns 24a may be patterned. The patterning the buffer layer 27a and the preliminary pad patterns 24a may include forming mask patterns extending in the X-direction, forming isolation holes 53 penetrating through the buffer layer 27a and the preliminary pad patterns 24a by performing an etching process using the mask patterns as an etch mask, and removing the mask patterns. The isolation holes 53 may expose the gate capping layer 21. The preliminary pad patterns 24a may be formed as pad patterns 24p spaced apart from each other in the X-direction by the isolation holes 53. Recess regions 53r connected to the isolation holes 53 may be formed on the upper surface of the bit line capping layer 50.

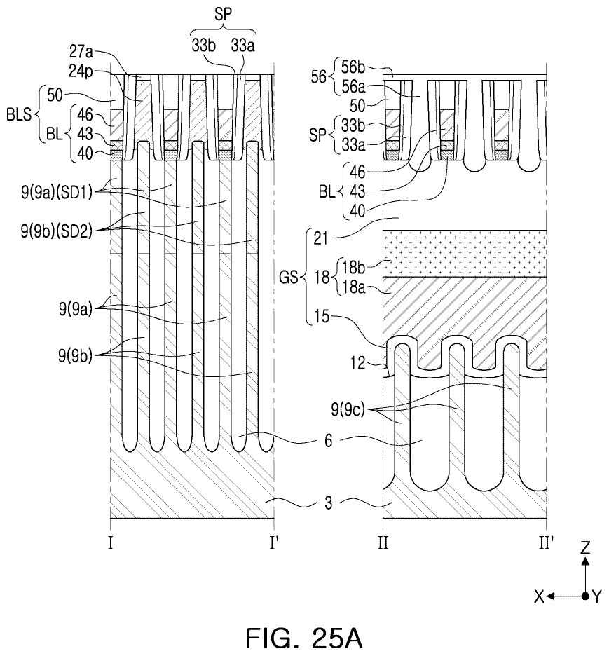

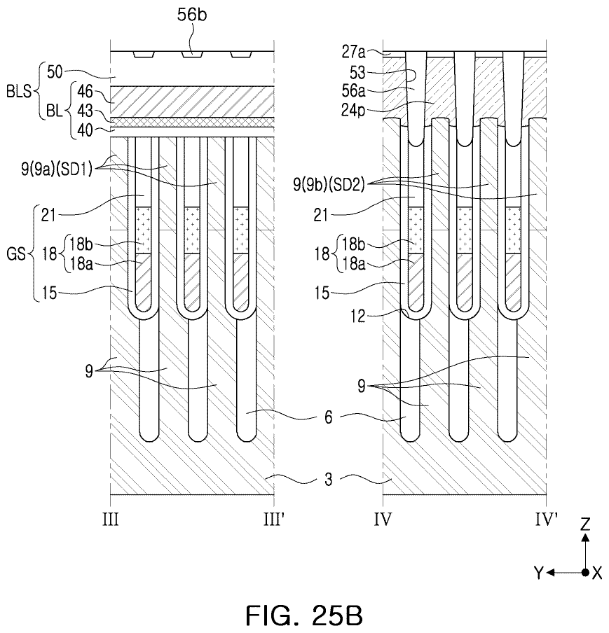

Referring to FIGS. 1A to 1D, and FIGS. 25A and 25B, insulating separation patterns 56 filling the isolation holes 53 and the recess regions 53r may be formed. The insulating separation patterns 56 may include first separation portions 56a filling the isolation holes 53 and second separation portions 56b filling the recess regions 53r.

Referring back to FIGS. 1A to 1D, and 2A to 3B, the interlayer insulating layer 60 may be formed. Contact holes 63 penetrating through the interlayer insulating layer 60 may be formed. The contact holes 63 may penetrate through the buffer layer 27a and may expose the pad patterns 24p. Each of the contact holes 63 may expose a portion of the pad pattern 24p and a portion of the bit line capping layer 50 adjacent to the pad pattern 24p.

The contact structures 69 may be formed in the contact holes 63. The forming the contact structure 69 may include forming a lower conductive layer 72 and an intermediate conductive layer 75 stacked in order by filling the lower region of the contact hole 63, forming an insulating spacer 82 covering the side surfaces of the contact hole 63 on the intermediate conductive layer 75, and forming an upper conductive layer 78 on the intermediate conductive layer 75.

Subsequently, an etch stop layer 85 and a data storage structure DS may be formed. The etch stop layer 85 may be formed on the interlayer insulating layer 60 and the contact structures 69. The forming the data storage structure DS may include forming first electrodes 88 penetrating through the etch stop layer 85 and electrically connected to the contact structures 69, forming a dielectric layer 90 covering the first electrodes 88, and forming a second electrode 92 on the dielectric layer 90.

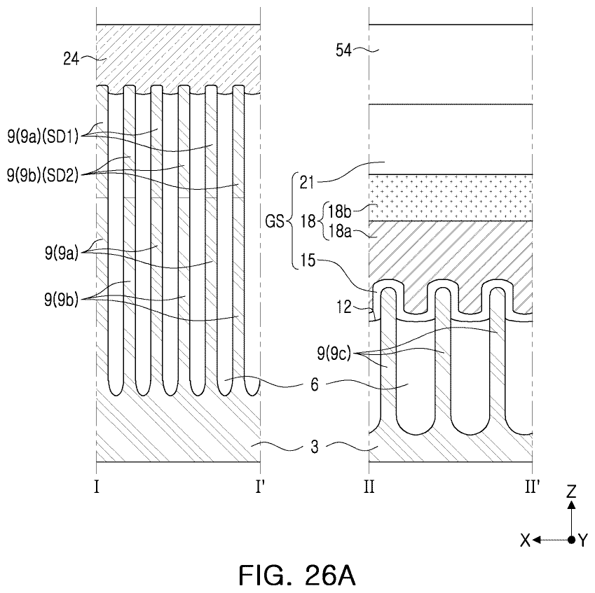

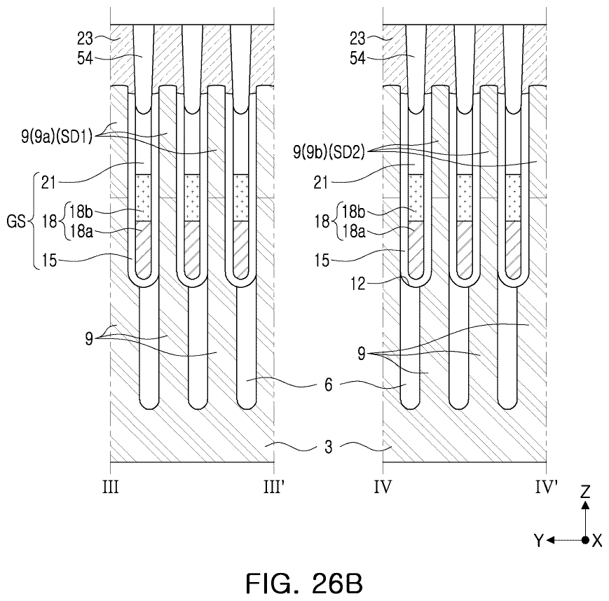

In the description below, a modified example of a semiconductor device forming method according to an example embodiment will be described with reference to FIGS. 26A to 29B. In FIGS. 26A to 29B, FIGS. 26A, 27A, 28A, and 29A are cross-sectional diagrams illustrating regions taken along lines I-I′ and II-II′ in FIG. 1A, and FIGS. 26B, 27B, FIGS. 28B and 29B are cross-sectional diagrams illustrating regions taken along lines III-III′ and lines IV-IV′ in FIG. 1A.

Referring to FIGS. 1A to 1D and FIGS. 26A and 26B, the preliminary pad layer (24 in FIGS. 21A and 21B) may be formed as in FIGS. 21A and 21B, pad lines 23 may be formed by patterning the preliminary pad layer (24 in FIGS. 21A and 21B), and insulating isolation lines 54 may be formed between the pad lines 23. Each of the pad lines 23 may have a line shape extending in the X-direction.

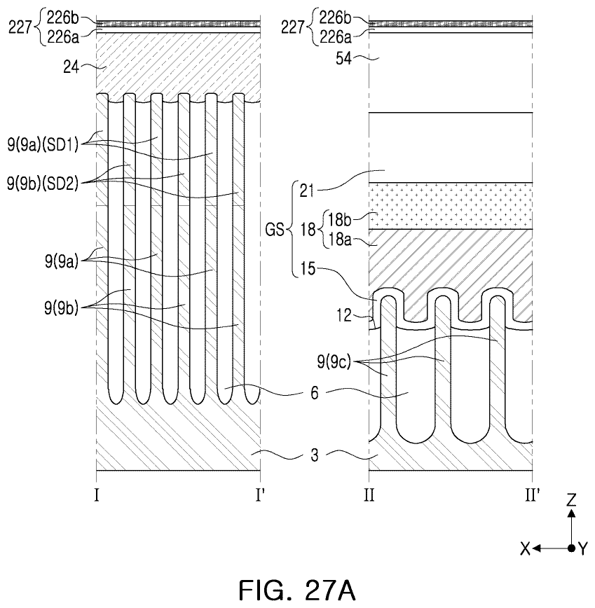

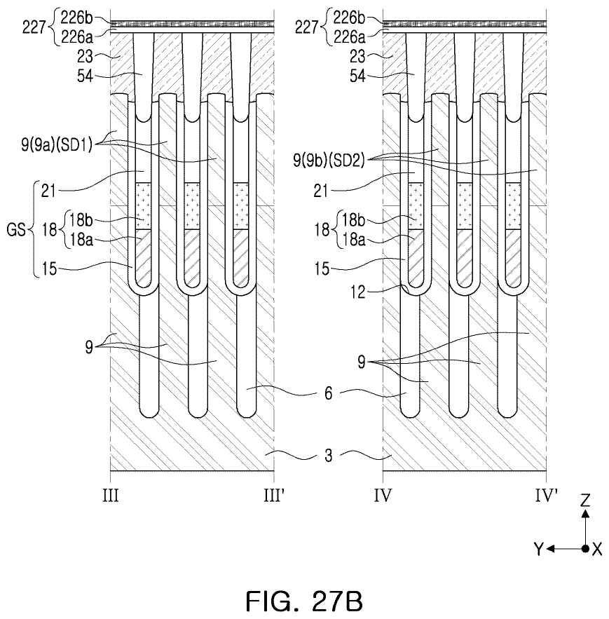

Referring to FIGS. 1A to 1D and FIGS. 27A and 27B, a preliminary buffer layer 227 may be formed on the pad lines 23 and the insulating isolation lines 54. The preliminary buffer layer 227 may include a first layer 226a and a second layer 226b stacked in order.

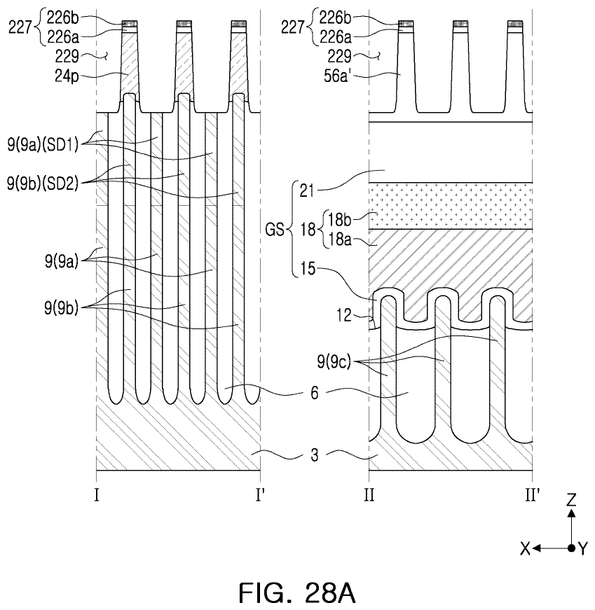

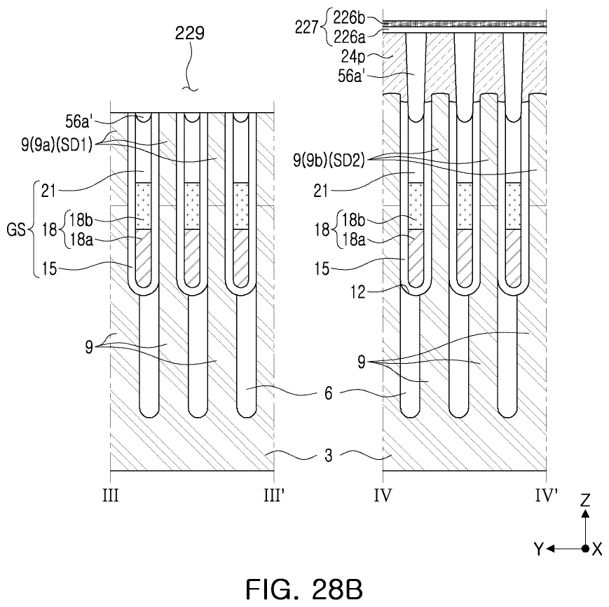

Referring to FIGS. 1A to 1D and FIGS. 28A and 28B, bit line trenches 229 may be formed by patterning the pad lines 23, the insulating isolation lines 54, and the preliminary buffer layer 227. The forming the bit line trenches 229 may include forming an opening exposing the first regions 9a by etching the pad lines 23, the insulating isolation lines 54, and the preliminary buffer layer 227, and partially etching the first regions 9a exposed by the opening. Accordingly, the first regions 9a may be formed to have upper surfaces disposed at a level lower than a level of the upper surfaces of the second regions 9b.

The pad lines 23 may be formed of pad patterns 24p spaced apart from each other in the X-direction by the bit line trenches 229. The insulating isolation lines 54 may include insulating material patterns 56a′ including portions disposed between the bit line trenches 229 and portions disposed below the bit line trenches 229.

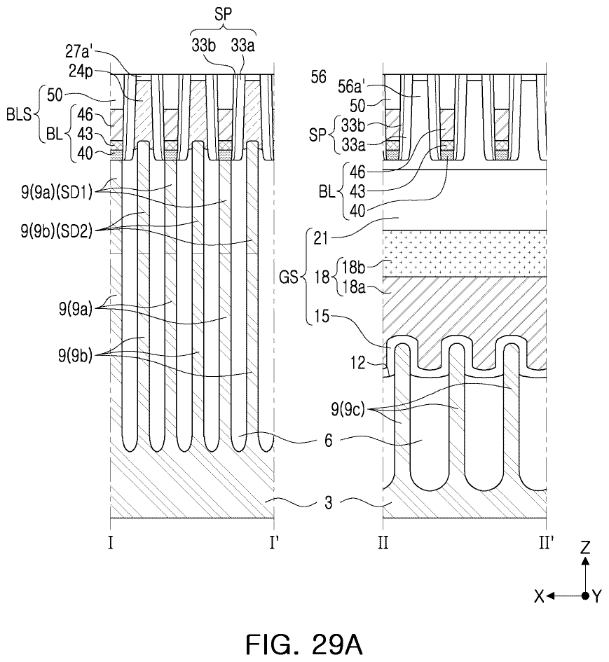

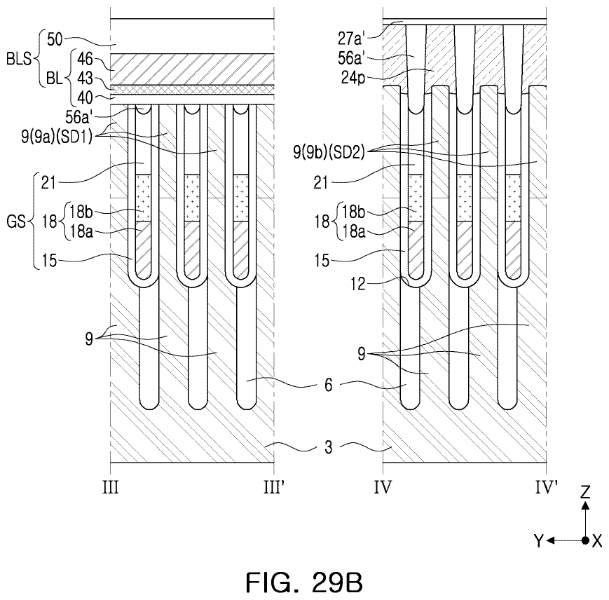

Referring to FIGS. 1A to 1D and FIGS. 29A and 29B, spacer structures SP may be formed on the side surfaces of the bit line trenches (229 in FIGS. 29A and 28B) by performing a spacer process. The forming the spacer structures SP may include forming a first spacer material layer and a second spacer material layer in order and forming first and second spacer layers 33a and 33b remaining on the side surfaces of the bit line trenches 30 by anisotropically etching the first and second spacer material layers.

Thereafter, bit line structures BLS may be formed. The forming the bit line structures BLS may include forming bit lines BL partially filling the bit line trenches (229 in FIGS. 28A and 28B) and forming bit line capping layers 50 on the bit lines BL. The forming the bit lines BL may include forming first material layers 40a in contact with the first regions 9a, and forming second material layers 43 and third material layers 46 in order on the first material layers 40a.

The forming the bit line capping layers 50 may include forming an insulating material layer filling the bit line trenches 30 on the bit lines BL and covering the preliminary buffer layer (227 in FIGS. 29A and 28B), and planarizing the insulating material layer until the first layer 226a of the preliminary buffer layer (227 in FIGS. 29A and 28B) is exposed.

While forming the bit line capping layers 50, the second layer 226b of the preliminary buffer layer 227 may be removed, and at least a portion of the first layer 226a may remain. The other first layer 226a of the preliminary buffer layer 227 may be defined as a buffer layer 27a′.

Referring back to FIGS. 1A to 1D, 4 and 5, the interlayer insulating layer 60, the contact structures 69, the etch stop layer 85 and the data storage structure DS may be formed in order in the same manner as described above. may

According to the aforementioned example embodiments, a semiconductor device may be provided, which may increase the contact area between the active region and the bit line, and may increase the contact area between the active region and the pad pattern. Also, according to example embodiments, a method of forming a bit line without a collapsing defect may be provided. Accordingly, a semiconductor device which may increase reliability and may improve performance while improving integration density may be provided.

While example embodiments have been illustrated and described above, it will be apparent to those skilled in the art that modifications and variations could be made without departing from the scope of inventive concepts in the present disclosure as defined by the appended claims.

What is claimed is:

1. A semiconductor device, comprising:
an active region on a substrate;
a device isolation layer on a side surface of the active region;
a gate trench intersecting the active region and extending into the device isolation layer, the active region including a first region and a second region spaced apart from each other by the gate trench;
a gate structure in the gate trench;
a bit line electrically connected to the first region of the active region; and
a pad pattern electrically connected to the second region of the active region,
wherein an upper surface of the second region of the active region is higher than an upper surface of the first region of the active region and lower than an upper surface of the bit line,
wherein a width of an upper region of the bit line is greater than a width of a lower region of the bit line,
wherein the pad pattern is in contact with the upper surface of the second region of the active region and a side surface of the second region of the active region, and
wherein an upper surface of the pad pattern is higher than the upper surface of the bit line.

2. The semiconductor device of claim 1,
wherein the gate structure includes a gate dielectric layer on an internal wall of the gate trench, a gate electrode partially filling the gate trench and on the gate dielectric layer, and a gate capping layer on the gate electrode, and
wherein the bit line is in contact with the gate capping layer and the gate dielectric layer.

3. The semiconductor device of claim 1, further comprising:
a bit line capping layer on the bit line; and
a spacer structure on a side surface of the bit line and a side surface of the bit line capping layer,
wherein the bit line capping layer includes an insulating material,
wherein the spacer structure includes a first spacer layer and a second spacer layer,
wherein the first spacer layer is spaced apart from the bit line, and
wherein at least a portion of the second spacer layer is between the first spacer layer and the bit line.

4. The semiconductor device of claim 3, wherein
a lower end of the first spacer layer is lower than a lower end of the pad pattern, and
the lower end of the first spacer layer is in contact with the device isolation layer.

5. The semiconductor device of claim 4, wherein an upper end of the first spacer layer is higher than the upper surface of the pad pattern.

6. The semiconductor device of claim 3, further comprising:
an insulating buffer pattern on the pad pattern,
wherein a side surface of the insulating buffer pattern is aligned with a side surface of the pad pattern, and
wherein an upper surface of the insulating buffer pattern, an upper surface of the spacer structure and an upper surface of the bit line capping layer are coplanar with each other.

7. The semiconductor device of claim 1, wherein a lower end of the bit line is lower than a lower end of the pad pattern.

8. The semiconductor device of claim 1, wherein a width of a lower region of the pad pattern is greater than a width of an upper region of the pad pattern.

9. The semiconductor device of claim 1, wherein
the bit line includes a first material layer and a second material layer on the first material layer,
the first material layer is connected to the first region of the active region,
a material of the second material layer is different from a material of the first material layer, and
a thickness of the second material layer is greater than a thickness of the first material layer.

10. The semiconductor device of claim 9, wherein an upper surface of the first material layer is lower than the upper surface of the second region of the active region.

11. The semiconductor device of claim 9, further comprising:
a spacer structure on a side surface of the bit line,
wherein the spacer structure includes a first spacer layer and a second spacer layer,
wherein the first spacer layer and the second material layer are on an upper surface of the first material layer,
wherein the first spacer layer is on a side surface of the second material layer,
wherein the second spacer layer covers a side surface of the first material layer and an external side surface of the first spacer layer,
wherein the second spacer layer is spaced apart from the second material layer, and
wherein a width of a lower surface of the second material layer is smaller than a width of an upper surface of the first material layer.

12. The semiconductor device of claim 9,
wherein the bit line further includes a third material layer between the first material layer and the second material layer, and
wherein the first material layer includes doped silicon.

13. A semiconductor device, comprising:
active regions on a substrate;
a device isolation layer on side surfaces of the active regions;
gate trenches intersecting the active regions and extending into the device isolation layer;
gate structures in the gate trenches, each of the active regions including a first region and a second region spaced apart from each other by one of the gate structures;
bit line structures connected to the first regions of the active regions; and
pad patterns connected to the second regions of the active regions,
wherein each of the gate structures has a line shape extending in a first direction,
wherein each of the bit line structures has a line shape extending in a second direction and the second direction is perpendicular to the first direction,
wherein the active regions are arranged in the first direction and a third direction, the third direction being diagonal with respect to the first direction,
wherein the first regions of the active regions and the second regions of the active regions are alternately arranged in the first direction between gate structures adjacent each other among the gate structures,
wherein each of the bit line structures includes a bit line and a bit line capping layer on the bit line such that the bit line structures include bit lines and bit line capping layers,
wherein the bit lines are connected to the first regions of the active regions, respectively, and
wherein each of the bit line structures includes a side surface having a negative slope.

14. The semiconductor device of claim 13, further comprising:
insulating separation patterns, wherein
the insulating separation patterns include first separation portions,
the first separation portions are between the pad patterns spaced apart from each other in the second direction, and
the first separation portions are between the bit line structures spaced apart from each other in the first direction.

15. The semiconductor device of claim 14, wherein
the insulating separation patterns further include second separation portions extending from upper regions of the first separation portions to upper surfaces of the bit line structures in the first direction.

16. The semiconductor device of claim 14, wherein the insulating separation patterns further include second separation portions extending to regions below lower surfaces of the bit line structures from lower regions of the first separation portions in the first direction.

17. The semiconductor device of claim 14, further comprising:
insulating buffer patterns on the pad patterns, wherein
upper surfaces of the insulating buffer patterns and upper surfaces of the insulating separation patterns are coplanar with each other.

18. The semiconductor device of claim 14, further comprising:
insulating buffer patterns on upper surfaces of the pad patterns and upper surfaces of the insulating separation patterns.

19. A semiconductor device, comprising:
active regions on a substrate;
a device isolation layer on side surfaces of the active regions;
gate trenches intersecting the active regions and extending into the device isolation layer;
gate structures in the gate trenches, each of the active regions including a first region and a second region spaced apart from each other by one of the gate structures, and each of the gate structures having a line shape extending in a first direction;
bit line structures connected to the first regions of the active regions, each of the bit line structures having a line shape extending in a second direction, the second direction being perpendicular to the first direction;
pad patterns between the bit line structures and connected to the second regions of the active regions;
insulating separation patterns including first separation portions, the first separation patterns being between the pad patterns spaced apart from each other in the second direction, and the first separation patterns being between the bit line structures spaced apart from each other in the first direction; and
spacer structures on side surfaces of the bit line structures, the spacer structures being between the bit line structures and the pad patterns, and the spacer structures being between the bit line structures and the insulating separation patterns,
wherein each of the gate structures includes a gate dielectric layer on an internal wall of the gate trench, a gate electrode partially filling the gate trench on the gate dielectric layer, and a gate capping insulating layer on the gate electrode,
wherein each of the active regions has a major axis extending in a direction diagonal to the first direction,
wherein the first regions of the active regions and the second regions of the active regions are alternately arranged in the first direction between gate structures adjacent to each other among the gate structures,
wherein each of the bit line structures includes a bit line connected to the first regions of the active regions and a bit line capping layer on the bit line,
wherein the insulating separation patterns further include second separation portions, and
wherein the second separation portions extend in the first direction from the first separation portions to upper surfaces of the bit line structures or the second separation portions extend in the first direction from the first separation portions to a region below lower surfaces of the bit line structures.

20. The semiconductor device of claim 19,
wherein each of the bit line structures includes a side surface having a negative slope,
wherein lower ends of the spacer structures are lower than lower ends of the pad patterns,
wherein upper ends of the spacer structures are higher than upper surfaces of the pad patterns, and
wherein the pad patterns are in contact with upper surfaces of the second regions of the active regions and the pad patterns are in contact with side surfaces of the second regions of the active regions.
